(19) United States
(12) Patent Application Publication
(10) Pub. No.: US 2026/0314015 A1
(43) Pub. Date: Oct. 8, 2026

(54) SEMICONDUCTOR DEVICE AND METHOD OF MAKING

(71) Applicant: Taiwan Semiconductor Manufacturing Company Limited, Hsin-Chu (TW)

(72) Inventors: Han Yu SHEN, Hsinchu County (TW); Ruei-Hung JANG, Jhubei City (TW); Chun-Li FANG, Pingzhen City (TW); Der-Ming KUO, Hsinchu County (TW)

(21) Appl. No.: 19/276,296

(22) Filed: Jul. 22, 2025

Related U.S. Application Data
(60) Provisional application No. 63/785,132, filed on Apr. 8, 2025.

(51) Int. Cl. H10D 64/00; H10D 30/01; H10D 30/47; H10D 62/85; H10D 64/01

(52) U.S. Cl. CPC H10D 64/111; H10D 30/015; H10D 30/475; H10D 62/8503; H10D 64/01

(57) ABSTRACT

A semiconductor device is provided. The semiconductor device includes a substrate, a source electrode over the substrate, a drain electrode over the substrate, a gate electrode between the source electrode and the drain electrode, and a multi-layer gate field plate (GAFP) including a bottom layer having a sidewall proximal the drain electrode. An angle of extension of an entirety of a bottom segment of the sidewall relative to a surface of the substrate is between about 50 degrees to about 130 degrees. The bottom segment of the sidewall spans at least about 25% of a vertical extent of the bottom layer.

### CROSS-REFERENCE TO RELATED APPLICATION

This application claims priority to U.S. provisional application 63/785,132, titled “Semiconductor device with field plate structure and method for manufacturing the same” and filed on Apr. 8, 2025, which is incorporated herein by reference in its entirety.

### BACKGROUND

Semiconductor devices are used in a multitude of electronic devices, such as mobile phones, laptops, desktops, tablets, watches, gaming systems, and various other industrial, commercial, and consumer electronics. Semiconductor devices generally comprise semiconductor portions and wiring portions formed inside the semiconductor portions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor device at a stage of fabrication, in accordance with some embodiments.

FIG. 2 illustrates a cross-sectional view of a semiconductor device at a stage of fabrication, in accordance with some embodiments.

FIG. 3 illustrates a cross-sectional view of a semiconductor device at a stage of fabrication, in accordance with some embodiments.

FIG. 4 illustrates a cross-sectional view of a semiconductor device at a stage of fabrication, in accordance with some embodiments.

FIG. 5 illustrates a cross-sectional view of a semiconductor device at a stage of fabrication, in accordance with some embodiments.

FIG. 6A illustrates a cross-sectional view of a semiconductor device at a stage of fabrication, in accordance with some embodiments.

FIG. 6B illustrates a cross-sectional view of a semiconductor device at a stage of fabrication, in accordance with some embodiments.

FIG. 7 illustrates a cross-sectional view of a semiconductor device at a stage of fabrication, in accordance with some embodiments.

FIG. 8 illustrates a cross-sectional view of a semiconductor device at a stage of fabrication, in accordance with some embodiments.

FIG. 9 illustrates a cross-sectional view of a semiconductor device at a stage of fabrication, in accordance with some embodiments.

FIG. 10 illustrates a cross-sectional view of a semiconductor device at a stage of fabrication, in accordance with some embodiments.

FIG. 11 illustrates a cross-sectional view of a semiconductor device at a stage of fabrication, in accordance with some embodiments.

FIG. 12A illustrates a cross-sectional view of a semiconductor device at a stage of fabrication, in accordance with some embodiments.

FIG. 12B illustrates a cross-sectional view of a semiconductor device at a stage of fabrication, in accordance with some embodiments.

FIG. 12C illustrates a cross-sectional view of a semiconductor device at a stage of fabrication, in accordance with some embodiments.

FIG. 12D illustrates a cross-sectional view of a semiconductor device at a stage of fabrication, in accordance with some embodiments.

FIG. 12E illustrates a cross-sectional view of a semiconductor device at a stage of fabrication, in accordance with some embodiments.

FIG. 12F illustrates a cross-sectional view of a semiconductor device at a stage of fabrication, in accordance with some embodiments.

FIG. 12G illustrates a cross-sectional view of a semiconductor device at a stage of fabrication, in accordance with some embodiments.

FIG. 13 illustrates a cross-sectional view of a semiconductor device at a stage of fabrication, in accordance with some embodiments.

FIG. 14A illustrates a cross-sectional view of a gate field plate (GAFP) of a semiconductor device, in accordance with some embodiments.

FIG. 14B illustrates a cross-sectional view of a GAFP of a semiconductor device, in accordance with some embodiments.

FIG. 14C illustrates a cross-sectional view of a GAFP of a semiconductor device, in accordance with some embodiments.

FIG. 14D illustrates a cross-sectional view of a GAFP of a semiconductor device, in accordance with some embodiments.

FIG. 14E illustrates a cross-sectional view of a GAFP of a semiconductor device, in accordance with some embodiments.

FIG. 14F illustrates a cross-sectional view of a GAFP of a semiconductor device, in accordance with some embodiments.

FIG. 15 illustrates a cross-sectional view of a semiconductor device at a stage of fabrication, in accordance with some embodiments.

FIG. 16 illustrates a cross-sectional view of a semiconductor device at a stage of fabrication, in accordance with some embodiments.

FIG. 17 illustrates a cross-sectional view of a semiconductor device at a stage of fabrication, in accordance with some embodiments.

FIG. 18 illustrates a cross-sectional view of a semiconductor device at a stage of fabrication, in accordance with some embodiments.

FIG. 19 illustrates a cross-sectional view of a semiconductor device at a stage of fabrication, in accordance with some embodiments.

FIG. 20 illustrates a cross-sectional view of a semiconductor device at a stage of fabrication, in accordance with some embodiments.

FIG. 21 illustrates a cross-sectional view of a semiconductor device at a stage of fabrication, in accordance with some embodiments.

FIG. 22 illustrates a cross-sectional view of a semiconductor device at a stage of fabrication, in accordance with some embodiments.

FIG. 23 illustrates an electrode arrangement representation associated with a semiconductor device, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

In some embodiments, a semiconductor device is provided. The semiconductor device includes a substrate, a source electrode over the substrate, a drain electrode over the substrate, a gate electrode between the source electrode and the drain electrode, and a gate field plate (GAFP) including a bottom layer having a sidewall proximal the drain electrode. An angle of extension of an entirety of a bottom segment of the sidewall relative to a surface of the substrate is between about 50 degrees to about 130 degrees, in accordance with some embodiments. In some embodiments, the bottom segment of the sidewall lacks a footing defect. At least one of the angle of extension being between about 50 degrees to about 130 degrees or the bottom segment of the sidewall lacking the footing defect provides for at least one of improved regulation or increased stability of an electric field in the semiconductor device, such as an electric field at a region between the GAFP and the drain electrode, enhanced breakdown voltage of the semiconductor device, improved reliability of the semiconductor device, increased chip probe (CP) yield, reduced failure rate, or other benefits.

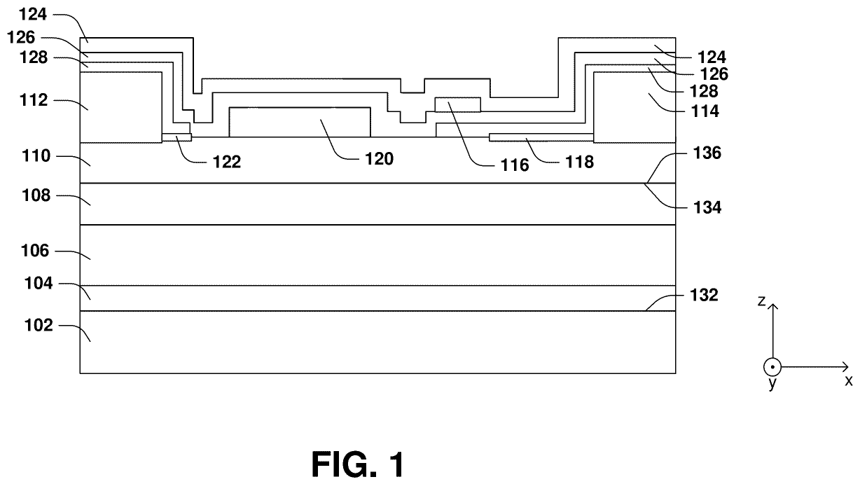

FIGS. 1-22 illustrate a semiconductor device 100 at various stages of fabrication, in accordance with some embodiments. FIGS. 1, 2, 3, 4, 5, 6A, 6B, 7, 8, 9, 10, 11, 12A, 12B, 12C, 12D, 12E, 12F, 12G, 13, 14A, 14B, 14C, 14D, 14E, 14F, 15, 16, 17, 18, 19, 20, 21, and 22 illustrate cross-sectional views of the semiconductor device 100. In some embodiments, the semiconductor device 100 comprises a power device, such as a power transistor. The power device comprises a gallium nitride-based power device. The semiconductor device 100 (e.g., the power device) comprises at least one of a field-effect transistor, a high electron mobility transistor (HEMT), a metal oxide semiconductor field effect transistor (MOSFET), or other suitable device. Other structures and/or configurations of the semiconductor device 100 are within the scope of the present disclosure.

FIG. 1 illustrates the semiconductor device 100 according to some embodiments. In some embodiments, the semiconductor device 100 comprises at least one of a semiconductor substrate 102, a buffer layer 104 over the semiconductor substrate 102, a bulk layer 106 over the buffer layer 104, a channel layer 108 over the bulk layer 106, a barrier layer 110 over the channel layer 108, a source electrode 112 over the barrier layer 110, a drain electrode 114 over the barrier layer 110, a feature 120 over the barrier layer 110, a first barrier structure 118, a second barrier structure 122, or one or more dielectric layers over at least one of the source electrode 112, the drain electrode 114, a field plate 116, the first barrier structure 118, or the barrier layer 110. In some embodiments, the one or more dielectric layers comprise at least one of a first dielectric layer 128, a second dielectric layer 126 over the first dielectric layer 128, or a third dielectric layer 124 over the second dielectric layer 126.

In some embodiments, the semiconductor substrate 102 comprises at least one of an epitaxial layer, a silicon-on-insulator (SOI) structure, a wafer, or a die formed from a wafer. In some embodiments, the semiconductor substrate 102 comprises at least one of silicon, germanium, SiC, SiGe, GaN, or other suitable material. The semiconductor substrate 102 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor substrate 102 are within the scope of the present disclosure. In some embodiments, the semiconductor substrate 102 comprises at least one of one or more n-doped regions or one or more p-doped regions. In some embodiments, the semiconductor substrate 102 is formed by at least one of physical vapor deposition (PVD), sputtering, chemical vapor deposition (CVD), metal-organic CVD (MOCVD), plasma enhanced CVD (PECVD), low pressure CVD (LPCVD), atomic layer chemical vapor deposition (ALCVD), ultrahigh vacuum CVD (UHVCVD), reduced pressure CVD (RPCVD), atomic layer deposition (ALD), molecular beam epitaxy (MBE), liquid phase epitaxy (LPE), spin on, growth, or other suitable techniques.

In some embodiments, the buffer layer 104 comprises at least one of AlN, AlGaN, GaN, or other suitable material. In some embodiments, the buffer layer 104 is formed by at least one of PVD, sputtering, CVD, MOCVD, PECVD, LPCVD, ALCVD, UHVCVD, RPCVD, ALD, MBE, LPE, spin on, growth, or other suitable techniques. The buffer layer 104 at least one of overlies the semiconductor substrate 102, is in direct contact with a surface 132 of the semiconductor substrate 102, or is in indirect contact with the surface 132 of the semiconductor substrate 102. The buffer layer 104 is different than the semiconductor substrate 102, such as having a different material composition, such that an interface is defined between the buffer layer 104 and the semiconductor substrate 102. In some embodiments, the buffer layer 104 does not have a material composition different than the semiconductor substrate 102. An interface is nevertheless defined between the buffer layer 104 and the semiconductor substrate 102 because the buffer layer 104 and the semiconductor substrate 102 are separate, different, etc. layers. In some embodiments, the interface is defined by a discontinuity (e.g., molecular discontinuity, a process-induced discontinuity, etc.) between the buffer layer 104 and the semiconductor substrate 102 and/or a difference in at least one of crystallinity, molecular structure, dopant concentration, etc. between the buffer layer 104 and the semiconductor substrate 102.

In some embodiments, the bulk layer 106 comprises at least one of GaN, GaAs, InP, or other suitable material. In some embodiments, the bulk layer 106 comprises a bulk GaN layer. In some embodiments, the bulk layer 106 comprises dopants. In some embodiments, the bulk layer 106 is formed by at least one of PVD, sputtering, CVD, MOCVD, PECVD, LPCVD, ALCVD, UHVCVD, RPCVD, ALD, MBE, LPE, spin on, growth, or other suitable techniques. The bulk layer 106 at least one of overlies the buffer layer 104, is in direct contact with a surface of the buffer layer 104, or is in indirect contact with the surface of the buffer layer 104. The bulk layer 106 is different than the buffer layer 104, such as having a different material composition, such that an interface is defined between the bulk layer 106 and the buffer layer 104. In some embodiments, the bulk layer 106 does not have a material composition different than the buffer layer 104. An interface is nevertheless defined between the bulk layer 106 and the buffer layer 104 because the bulk layer 106 and the buffer layer 104 are separate, different, etc. layers. In some embodiments, the interface is defined by a discontinuity (e.g., molecular discontinuity, a process-induced discontinuity, etc.) between the bulk layer 106 and the buffer layer 104 and/or a difference in at least one of crystallinity, molecular structure, dopant concentration, etc. between the bulk layer 106 and the buffer layer 104.

In some embodiments, the channel layer 108 comprises at least one of GaN (e.g., undoped GaN), GaAs, InP, or other suitable material. In some embodiments, the channel layer 108 is undoped. In some embodiments, the channel layer 108 comprises an undoped GaN layer. In some embodiments, the channel layer 108 comprises a channel region of the power device. In some embodiments, a dopant concentration of the channel layer 108 is less than a dopant concentration of the bulk layer 106. In some embodiments, the channel layer 108 is formed by at least one of PVD, sputtering, CVD, MOCVD, PECVD, LPCVD, ALCVD, UHVCVD, RPCVD, ALD, MBE, LPE, spin on, growth, or other suitable techniques. The channel layer 108 at least one of overlies the bulk layer 106, is in direct contact with a surface of the bulk layer 106, or is in indirect contact with the surface of the bulk layer 106. The channel layer 108 is different than the bulk layer 106, such as having a different material composition, such that an interface is defined between the channel layer 108 and the bulk layer 106. In some embodiments, the channel layer 108 does not have a material composition different than the bulk layer 106. An interface is nevertheless defined between the channel layer 108 and the bulk layer 106 because the channel layer 108 and the bulk layer 106 are separate, different, etc. layers. In some embodiments, the interface is defined by a discontinuity (e.g., molecular discontinuity, a process-induced discontinuity, etc.) between the channel layer 108 and the bulk layer 106 and/or a difference in at least one of crystallinity, molecular structure, dopant concentration, etc. between the channel layer 108 and the bulk layer 106.

In some embodiments, the barrier layer 110 comprises at least one of AlGaN, InAlN, AlN, AlGaAs, InAlAs, InGaAs, or other suitable material. In some embodiments, the barrier layer 110 comprises an AlGaN barrier layer. In some embodiments, the barrier layer 110 is formed by at least one of PVD, sputtering, CVD, MOCVD, PECVD, LPCVD, ALCVD, UHVCVD, RPCVD, ALD, MBE, LPE, spin on, growth, or other suitable techniques. The barrier layer 110 at least one of overlies the channel layer 108, is in direct contact with a surface 134 of the channel layer 108, or is in indirect contact with the surface 134 of the channel layer 108. The barrier layer 110 is different than the channel layer 108, such as having a different material composition, such that an interface is defined between the barrier layer 110 and the channel layer 108. In some embodiments, the barrier layer 110 does not have a material composition different than the channel layer 108. An interface is nevertheless defined between the barrier layer 110 and the channel layer 108 because the barrier layer 110 and the channel layer 108 are separate, different, etc. layers. In some embodiments, the interface is defined by a discontinuity (e.g., molecular discontinuity, a process-induced discontinuity, etc.) between the barrier layer 110 and the channel layer 108 and/or a difference in at least one of crystallinity, molecular structure, dopant concentration, etc. between the barrier layer 110 and the channel layer 108.

In some embodiments, the semiconductor device 100 comprises an electron layer (not shown) between the channel layer 108 and the barrier layer 110. In some embodiments, the electron layer comprises a Two Dimensional Electron Gas (2DEG) layer. In some embodiments, the electron layer is formed by charge accumulation at an interface between the surface 134 (e.g., top surface) of the channel layer 108 and a surface 136 (e.g., bottom surface) of the barrier layer 110. In some embodiments, the charge accumulation is due, at least in part, to a polarization difference between the channel layer 108 and the barrier layer 110. In some embodiments, the electron layer provides high-mobility conduction along a plane between the channel layer 108 and the barrier layer 110. In some embodiments, the plane is parallel to at least one of the surface 134 of the channel layer 108, the surface 136 of the barrier layer 110, the surface 132 of the semiconductor substrate 102, or an x-axis (shown in FIGS. 1-23).

In some embodiments, the source electrode 112 comprises at least one of Ti, TiN, TaN, Al, Cu, AlCu, NiSi, CoSi, Mo, W, Co, Zr, Pt, Au, or other suitable material. In some embodiments, the source electrode 112 is formed by at least one of PVD, sputtering, CVD, MOCVD, PECVD, LPCVD, ALCVD, UHVCVD, RPCVD, ALD, MBE, LPE, spin on, growth, or other suitable techniques. The source electrode 112 at least one of overlies the barrier layer 110, is in direct contact with a surface of the barrier layer 110, or is in indirect contact with the surface of the barrier layer 110.

In some embodiments, the drain electrode 114 comprises at least one of Ti, TiN, TaN, Al, Cu, AlCu, NiSi, CoSi, Mo, W, Co, Zr, Pt, Au, or other suitable material. In some embodiments, the drain electrode 114 is formed by at least one of PVD, sputtering, CVD, MOCVD, PECVD, LPCVD, ALCVD, UHVCVD, RPCVD, ALD, MBE, LPE, spin on, growth, or other suitable techniques. The drain electrode 114 at least one of overlies the barrier layer 110, is in direct contact with a surface of the barrier layer 110, or is in indirect contact with the surface of the barrier layer 110.

In some embodiments, the feature 120 comprises at least one of GaN, GaAs, InP, or other suitable feature. In some embodiments, the feature 120 is formed by at least one of PVD, sputtering, CVD, MOCVD, PECVD, LPCVD, ALCVD, UHVCVD, RPCVD, ALD, MBE, LPE, spin on, growth, or other suitable techniques. The feature 120 comprises p-type dopants and the feature 120 is a p-type feature, such as a p-type GaN structure. Other configurations (e.g., n-type feature or other type of feature) of the feature 120 are within the scope of the present disclosure. The feature 120 at least one of overlies the barrier layer 110, is in direct contact with a surface of the barrier layer 110, or is in indirect contact with the surface of the barrier layer 110.

In some embodiments, the field plate 116 comprises at least one of TiN, Al, Ni, Au, Cu, Pt, or other suitable material. In some embodiments, the field plate 116 is formed by at least one of PVD, sputtering, CVD, MOCVD, PECVD, LPCVD, ALCVD, UHVCVD, RPCVD, ALD, MBE, LPE, spin on, growth, or other suitable techniques. The field plate 116 at least one of overlies the second dielectric layer 126, is in direct contact with a surface of the second dielectric layer 126, or is in indirect contact with the surface of the second dielectric layer 126.

In some embodiments, the first barrier structure 118 comprises at least one of AlGaN, InAlN, AlN, AlGaAs, InAlAs, InGaAs, or other suitable material. In some embodiments, the first barrier structure 118 comprises a first AlGaN-2 barrier structure. In some embodiments, the first barrier structure 118 is formed by at least one of PVD, sputtering, CVD, MOCVD, PECVD, LPCVD, ALCVD, UHVCVD, RPCVD, ALD, MBE, LPE, spin on, growth, or other suitable techniques. The first barrier structure 118 at least one of overlies the barrier layer 110, is in direct contact with a surface of the barrier layer 110, or is in indirect contact with the surface of the barrier layer 110.

In some embodiments, the second barrier structure 122 comprises at least one of AlGaN, InAlN, AlN, AlGaAs, InAlAs, InGaAs, or other suitable material. In some embodiments, the second barrier structure 122 comprises a second AlGaN-2 barrier structure. In some embodiments, the second barrier structure 122 is formed by at least one of PVD, sputtering, CVD, MOCVD, PECVD, LPCVD, ALCVD, UHVCVD, RPCVD, ALD, MBE, LPE, spin on, growth, or other suitable techniques. The second barrier structure 122 at least one of overlies the barrier layer 110, is in direct contact with a surface of the barrier layer 110, or is in indirect contact with the surface of the barrier layer 110.

The first dielectric layer 128 comprises silicon nitride. Other materials (e.g., dielectric materials) of the first dielectric layer 128 are within the scope of the present disclosure. In some embodiments, the first dielectric layer 128 is formed by at least one of PVD, sputtering, CVD, MOCVD, PECVD, LPCVD, ALCVD, UHVCVD, RPCVD, ALD, MBE, LPE, spin on, growth, or other suitable techniques. The first dielectric layer 128 at least one of overlies the source electrode 112, is in direct contact with a surface of the source electrode 112, or is in indirect contact with the surface of the source electrode 112. The first dielectric layer 128 at least one of overlies the drain electrode 114, is in direct contact with a surface of the drain electrode 114, or is in indirect contact with the surface of the drain electrode 114. The first dielectric layer 128 at least one of overlies the first barrier structure 118, is in direct contact with a surface of the first barrier structure 118, or is in indirect contact with the surface of the first barrier structure 118. The first dielectric layer 128 at least one of overlies the second barrier structure 122, is in direct contact with a surface of the second barrier structure 122, or is in indirect contact with the surface of the second barrier structure 122.

In some embodiments, the second dielectric layer 126 comprises a low-k dielectric material. As used herein, the term “low-k dielectric material” refers to a material having a dielectric constant, k, lower than about 3.9. In some embodiments, the second dielectric layer 126 comprises at least one of SiO₂, SiON, SiOC, SiOCN, or other suitable material. In some embodiments, the second dielectric layer 126 is formed by at least one of PVD, sputtering, CVD, MOCVD, PECVD, LPCVD, ALCVD, UHVCVD, RPCVD, ALD, MBE, LPE, spin on, growth, or other suitable techniques. The second dielectric layer 126 at least one of overlies the first dielectric layer 128, is in direct contact with a surface of the first dielectric layer 128, or is in indirect contact with the surface of the first dielectric layer 128. The second dielectric layer 126 at least one of overlies the barrier layer 110, is in direct contact with a surface of the barrier layer 110, or is in indirect contact with the surface of the barrier layer 110. The second dielectric layer 126 at least one of overlies the feature 120, is in direct contact with a surface of the feature 120, or is in indirect contact with the surface of the feature 120.

In some embodiments, the third dielectric layer 124 comprises silicon nitride. Other materials (e.g., dielectric materials) of the third dielectric layer 124 are within the scope of the present disclosure. In some embodiments, the third dielectric layer 124 is formed by at least one of PVD, sputtering, CVD, MOCVD, PECVD, LPCVD, ALCVD, UHVCVD, RPCVD, ALD, MBE, LPE, spin on, growth, or other suitable techniques. A thickness 130 of the third dielectric layer 124 is between about 700 angstroms to about 1,300 angstroms. Other values of the thickness 130 are within the scope of the present disclosure. The third dielectric layer 124 at least one of overlies the second dielectric layer 126, is in direct contact with a surface of the second dielectric layer 126, or is in indirect contact with the surface of the second dielectric layer 126. The third dielectric layer 124 at least one of overlies the field plate 116, is in direct contact with a surface of the field plate 116, or is in indirect contact with the surface of the field plate 116.

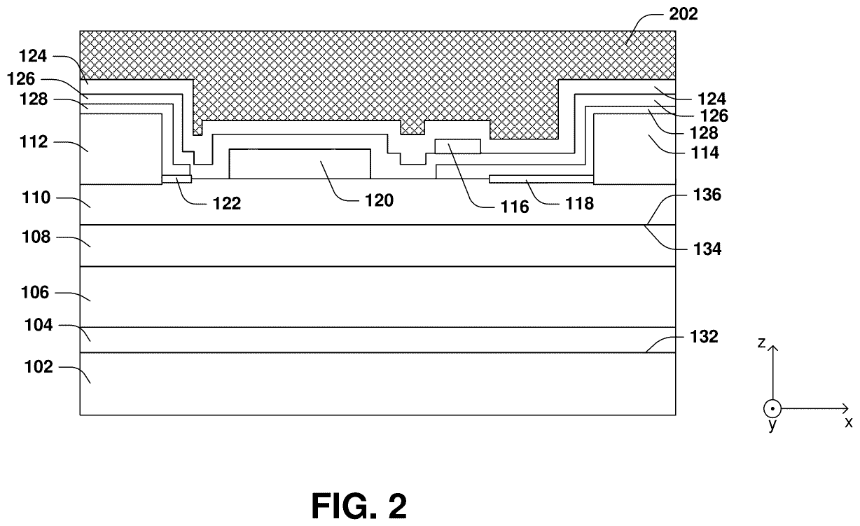

FIG. 2 illustrates a first mask layer 202 formed over the third dielectric layer 124, according to some embodiments. The first mask layer 202 at least one of overlies the third dielectric layer 124, is in direct contact with a surface of the third dielectric layer 124, or is in indirect contact with the surface of the third dielectric layer 124. The first mask layer 202 is formed by at least one of PVD, sputtering, CVD, PECVD, LPCVD, ALCVD, UHVCVD, RPCVD, ALD, MBE, LPE, spin on, growth, or other suitable techniques.

In some embodiments, the first mask layer 202 comprises a photoresist having a light-sensitive material, where properties, such as solubility, of the first mask layer 202 are affected by light. In some embodiments, the first mask layer 202 is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist.

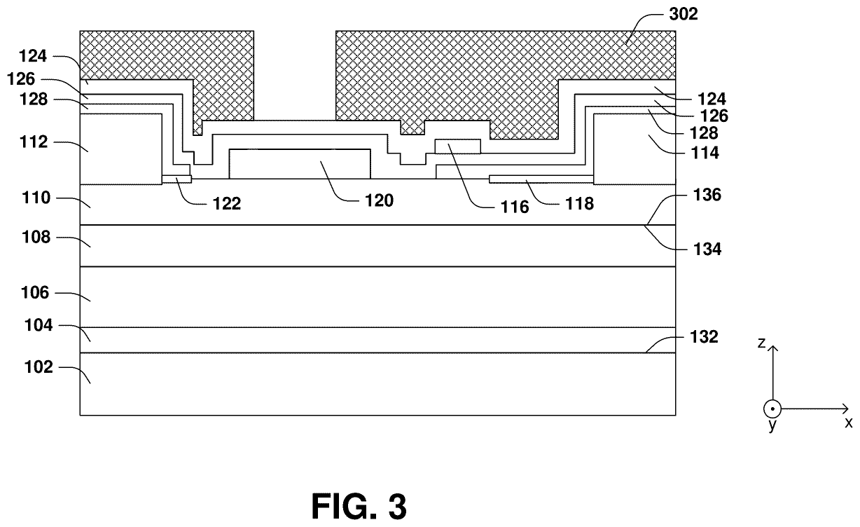

FIG. 3 illustrates a first patterned mask layer 302 formed from the first mask layer 202, according to some embodiments. In some embodiments, the first patterned mask layer 302 defines an opening exposing a portion of the third dielectric layer 124. Even though one opening in the first patterned mask layer 302 are depicted in FIG. 3, any number of openings in the first patterned mask layer 302 are contemplated.

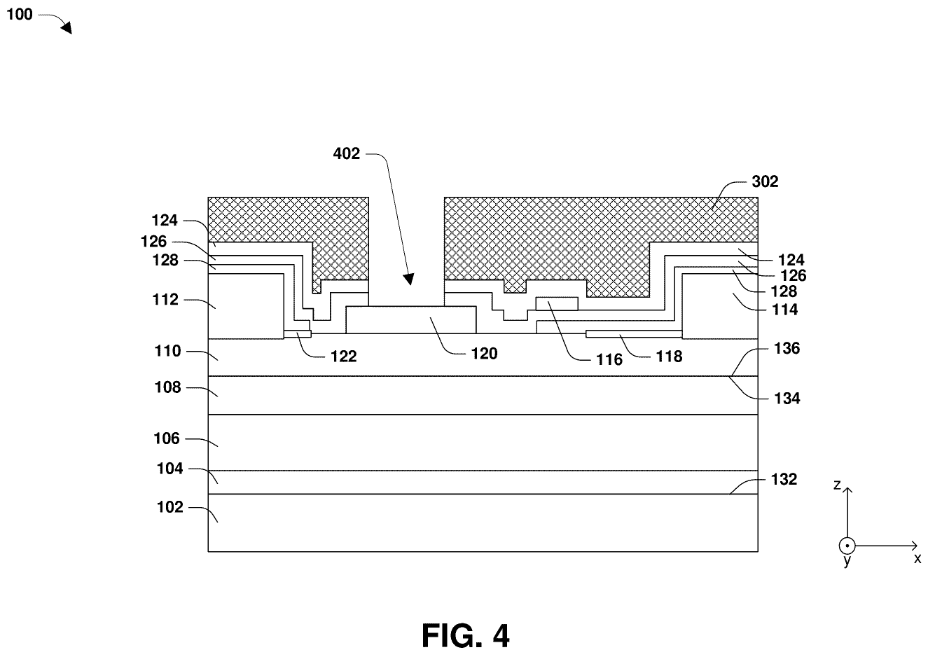

FIG. 4 illustrate use of the first patterned mask layer 302 to form a first trench 402 in the one or more dielectric layers, according to some embodiments. In some embodiments, the first trench 402 exposes a surface of the feature 120. The first trench 402 extends through at least one of the third dielectric layer 124 or the second dielectric layer 126. In some embodiments, a first etching process is performed to form the first trench 402, where the opening in the first patterned mask layer 302 allows one or more etchants applied during the first etching process to remove portions of one or more first target layers over the feature 120 while the first patterned mask layer 302 protects or shields portions of the one or more first target layers that are covered by the first patterned mask layer 302 to form the first trench 402. In some embodiments, the one or more first target layers (etched by the first etching process to produce the first trench 402) comprises at least one of the third dielectric layer 124 or the second dielectric layer 126.

In some embodiments, the first etching process comprises at least one of a dry etching process (e.g., a reactive ion etching (RIE) process or other suitable dry etching process), a wet etching process, an anisotropic etching process, an isotropic etching process, or other suitable etching process. The first etching process uses one or more first etching chemicals comprising at least one of plasma, fluorine, hydrogen fluoride (HF), diluted HF, sulfur hexafluoride (SF₆), a chlorine compound such as hydrogen chloride (HCl₂), hydrogen sulfide (H₂S), tetrafluoromethane (CF₄), or other suitable material. In some embodiments, the one or more first etching chemicals have an etching selectivity such that the first etching process removes and/or etches away portions of the one or more first target layers while removing and/or etching away little to none of the feature 120.

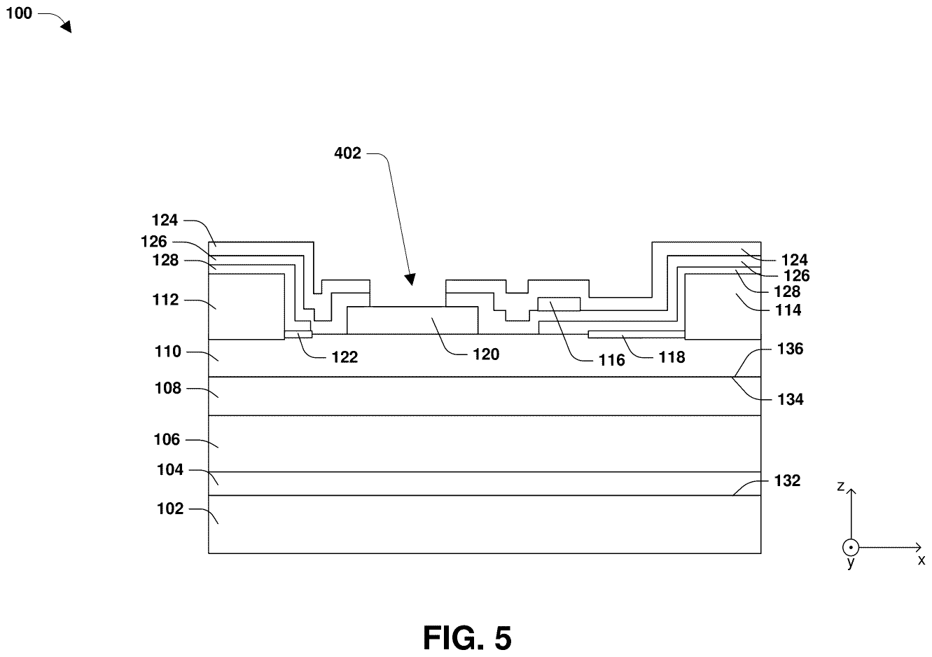

FIG. 5 illustrates removal of the first patterned mask layer 302, according to some embodiments. In some embodiments, the first patterned mask layer 302 is removed after the first trench 402 are formed. The first patterned mask layer 302 is removed by at least one of performing a washing process to wash the first patterned mask layer 302 away, stripping the first patterned mask layer 302 away, etching the first patterned mask layer 302, chemical mechanical planarization (CMP), or other suitable techniques.

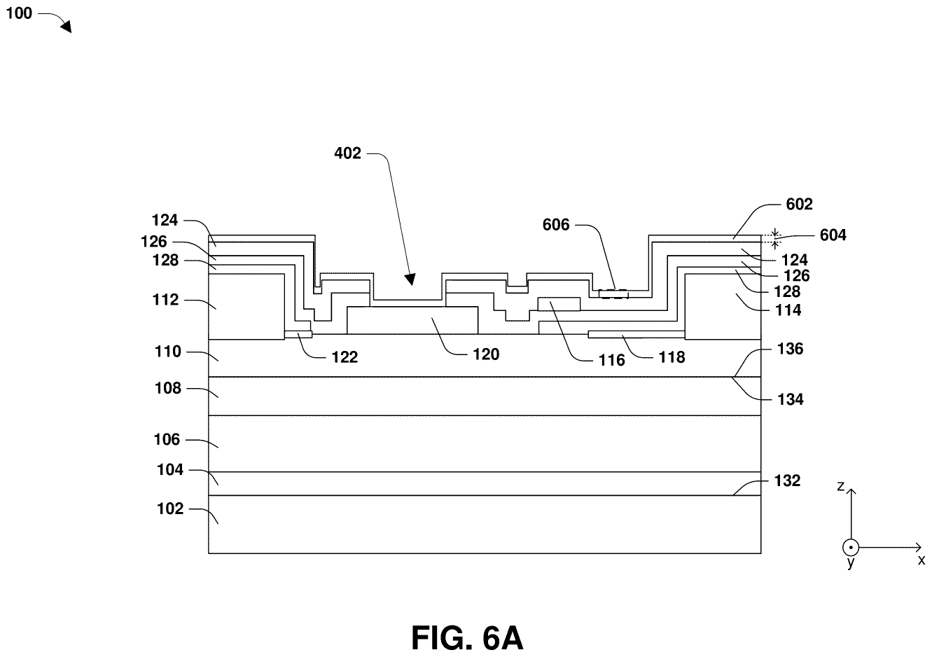

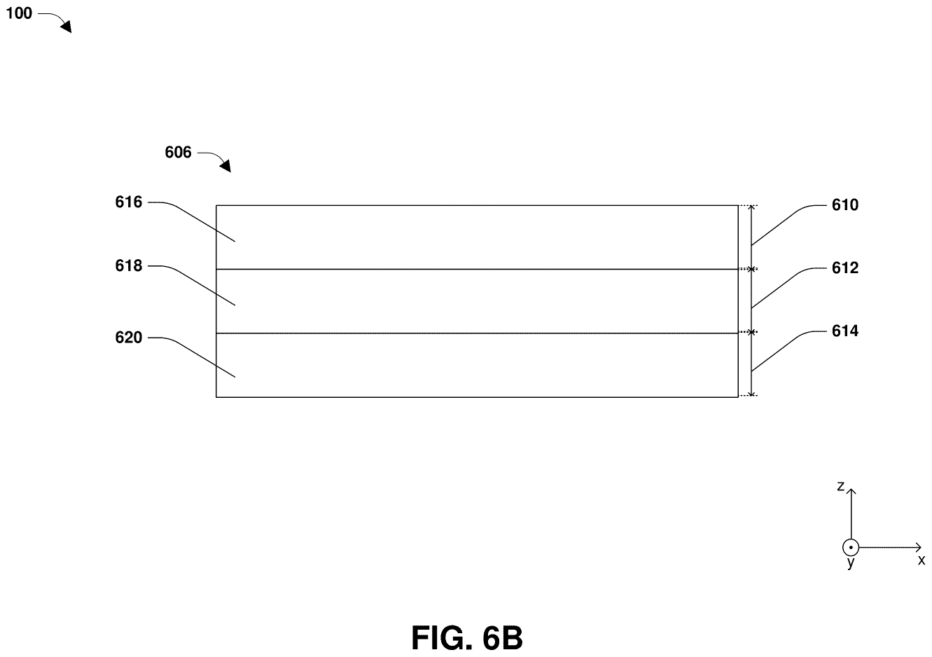

FIG. 6A illustrates a first electrode layer 602 formed over the third dielectric layer 124 and/or in the first trench 402, according to some embodiments. The first electrode layer 602 at least one of overlies the third dielectric layer 124, is in direct contact with a surface of the third dielectric layer 124, or is in indirect contact with the surface of the third dielectric layer 124. The first electrode layer 602 at least one of overlies the feature 120, is in direct contact with the surface of the feature 120 (exposed by the first trench 402, for example), or is in indirect contact with the surface of the feature 120. The first electrode layer 602 is formed by at least one of PVD, sputtering, CVD, PECVD, LPCVD, ALCVD, UHVCVD, RPCVD, ALD, MBE, LPE, spin on, growth, or other suitable techniques. The first electrode layer 602 comprises at least one of TiN, Ti, TiW, TaN, TiAlN, TaAlN, HfN, or other suitable material. A thickness 604 of the first electrode layer 602 is between about 600 angstroms to about 1,800 angstroms. Other values of the thickness 604 are within the scope of the present disclosure.

FIG. 6B illustrates an enlarged view of a portion 606 (shown with a dashed-line outline in FIG. 6A) of the first electrode layer 602, in accordance with some embodiments. In some embodiments, the first electrode layer 602 comprises at least one of a first layer 620, a second layer 618 over the first layer 620, or a third layer 616 over the second layer 618. The first layer 620 at least one of overlies the third dielectric layer 124, is in direct contact with the surface of the third dielectric layer 124, or is in indirect contact with the surface of the third dielectric layer 124. The first layer 620 at least one of overlies the feature 120, is in direct contact with the top surface of the feature 120, or is in indirect contact with the top surface of the feature 120. The first layer 620 is formed by at least one of PVD, sputtering, CVD, PECVD, LPCVD, ALCVD, UHVCVD, RPCVD, ALD, MBE, LPE, spin on, growth, or other suitable techniques. The first layer 620 comprises TiN. In some embodiments, the first layer 620 additionally or alternatively comprises one or more other materials, such as at least one of Ti, TiW, TaN, TiAlN, TaAlN, HfN, or other suitable material. A thickness 614 of the first layer 620 is between about 100 angstroms to about 500 angstroms. Other values of the thickness 614 are within the scope of the present disclosure.

The second layer 618 at least one of overlies the first layer 620, is in direct contact with the top surface of the first layer 620, or is in indirect contact with the top surface of the first layer 620. The second layer 618 is formed by at least one of PVD, sputtering, CVD, PECVD, LPCVD, ALCVD, UHVCVD, RPCVD, ALD, MBE, LPE, spin on, growth, or other suitable techniques. The second layer 618 comprises Ti. In some embodiments, the second layer 618 additionally or alternatively comprises one or more other materials, such as at least one of TiN, TiW, TaN, TiAlN, TaAlN, HfN, or other suitable material. A thickness 612 of the second layer 618 is between about 400 angstroms to about 800 angstroms. Other values of the thickness 612 are within the scope of the present disclosure. In some embodiments, the thickness 612 of the second layer 618 is controlled to control a Ti concentration of the first electrode layer 602. The second layer 618 is different than the first layer 620, such as having a different material composition, such that an interface is defined between the second layer 618 and the first layer 620. In some embodiments, the second layer 618 does not have a material composition different than the first layer 620. An interface is nevertheless defined between the second layer 618 and the first layer 620 because the second layer 618 and the first layer 620 are separate, different, etc. layers. In some embodiments, the interface is defined by a discontinuity (e.g., molecular discontinuity, a process-induced discontinuity, etc.) between the second layer 618 and the first layer 620 and/or a difference in at least one of crystallinity, molecular structure, dopant concentration, etc. between the second layer 618 and the first layer 620. In some embodiments, an alloy is formed between the second layer 618 and the first layer 620.

The third layer 616 at least one of overlies the second layer 618, is in direct contact with the top surface of the second layer 618, or is in indirect contact with the top surface of the second layer 618. The third layer 616 is formed by at least one of PVD, sputtering, CVD, PECVD, LPCVD, ALCVD, UHVCVD, RPCVD, ALD, MBE, LPE, spin on, growth, or other suitable techniques. The third layer 616 comprises TiN. In some embodiments, the third layer 616 additionally or alternatively comprises one or more other materials, such as at least one of Ti, TiW, TaN, TiAlN, TaAlN, HfN, or other suitable material. A thickness 610 of the third layer 616 is between about 100 angstroms to about 500 angstroms. Other values of the thickness 610 are within the scope of the present disclosure. The third layer 616 is different than the second layer 618, such as having a different material composition, such that an interface is defined between the third layer 616 and the second layer 618. In some embodiments, the third layer 616 does not have a material composition different than the second layer 618. An interface is nevertheless defined between the third layer 616 and the second layer 618 because the third layer 616 and the second layer 618 are separate, different, etc. layers. In some embodiments, the interface is defined by a discontinuity (e.g., molecular discontinuity, a process-induced discontinuity, etc.) between the third layer 616 and the second layer 618 and/or a difference in at least one of crystallinity, molecular structure, dopant concentration, etc. between the third layer 616 and the second layer 618. In some embodiments, an alloy is formed between the third layer 616 and the second layer 618.

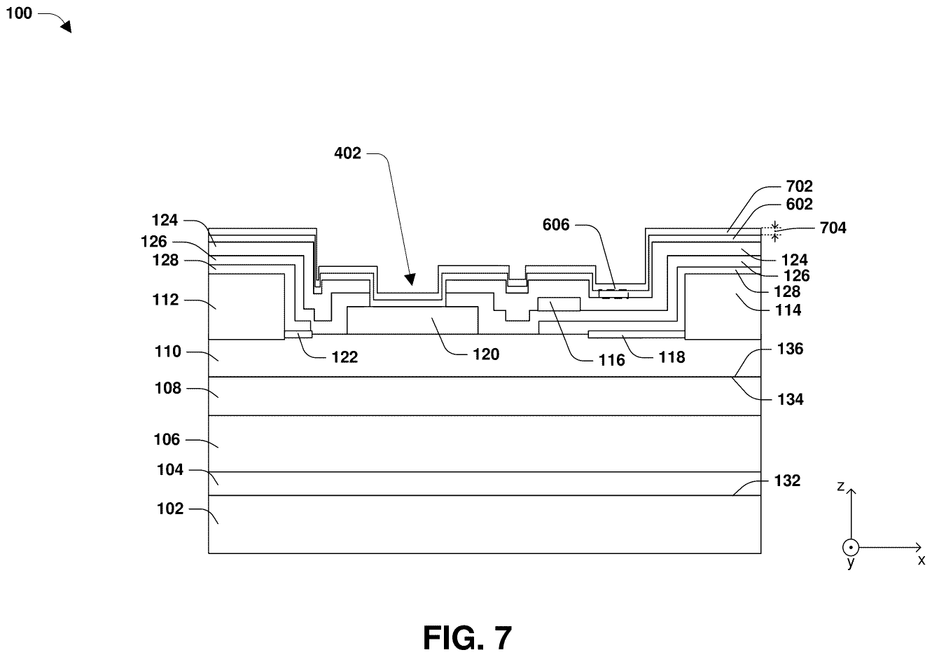

FIG. 7 illustrates a second electrode layer 702 formed over the first electrode layer 602, according to some embodiments. The second electrode layer 702 at least one of overlies the first electrode layer 602, is in direct contact with a surface of the first electrode layer 602, or is in indirect contact with the surface of the first electrode layer 602. The second electrode layer 702 is formed by at least one of PVD, sputtering, CVD, PECVD, LPCVD, ALCVD, UHVCVD, RPCVD, ALD, MBE, LPE, spin on, growth, or other suitable techniques. The second electrode layer 702 comprises AlCu. In some embodiments, the second electrode layer 702 additionally or alternatively comprises one or more other materials, such as at least one of Co, Al, Cu, Mo, Ru, W, Ta, or other suitable material. A thickness 704 of the second electrode layer 702 is between about 1,000 angstroms to about 1,500 angstroms. Other values of the thickness 704 are within the scope of the present disclosure.

The second electrode layer 702 is different than the first electrode layer 602, such as having a different material composition, such that an interface is defined between the second electrode layer 702 and the first electrode layer 602. In some embodiments, the second electrode layer 702 does not have a material composition different than the first electrode layer 602. An interface is nevertheless defined between the second electrode layer 702 and the first electrode layer 602 because the second electrode layer 702 and the first electrode layer 602 are separate, different, etc. layers. In some embodiments, the interface is defined by a discontinuity (e.g., molecular discontinuity, a process-induced discontinuity, etc.) between the second electrode layer 702 and the first electrode layer 602 and/or a difference in at least one of crystallinity, molecular structure, dopant concentration, etc. between the second electrode layer 702 and the first electrode layer 602.

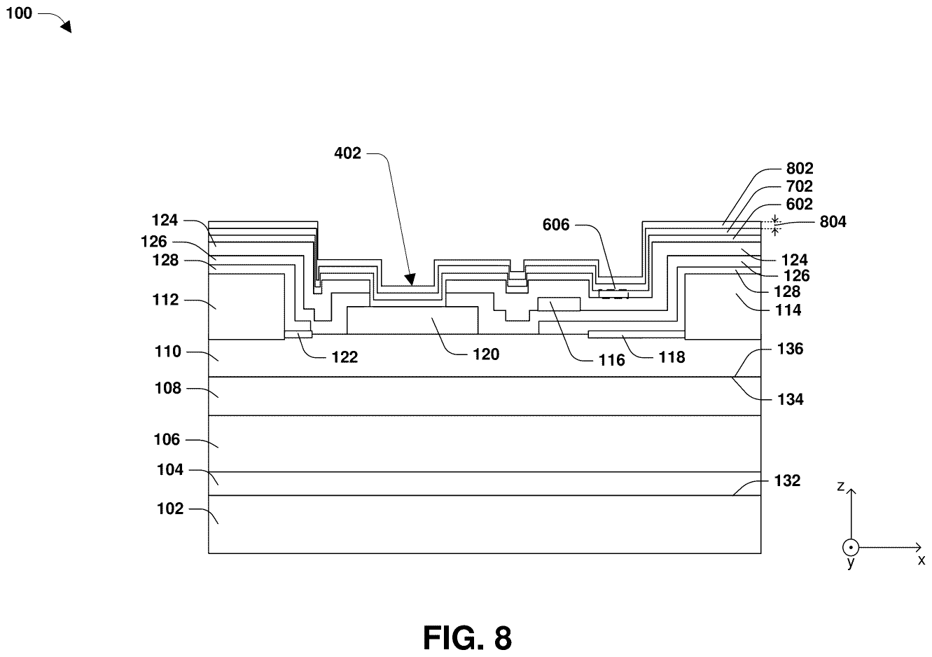

FIG. 8 illustrates a third electrode layer 802 formed over the second electrode layer 702, according to some embodiments. The third electrode layer 802 at least one of overlies the second electrode layer 702, is in direct contact with a surface of the second electrode layer 702, or is in indirect contact with the surface of the second electrode layer 702. The third electrode layer 802 is formed by at least one of PVD, sputtering, CVD, PECVD, LPCVD, ALCVD, UHVCVD, RPCVD, ALD, MBE, LPE, spin on, growth, or other suitable techniques. The third electrode layer 802 comprises TiN. In some embodiments, the third electrode layer 802 additionally or alternatively comprises one or more other materials, such as at least one of Ti, TiW, SiN, SiO₂, Al₂O₃, AlN, TaN, TiAlN, or other suitable material. A thickness 804 of the third electrode layer 802 is between about 800 angstroms to about 1,300 angstroms. Other values of the thickness 804 are within the scope of the present disclosure.

The third electrode layer 802 is different than the second electrode layer 702, such as having a different material composition, such that an interface is defined between the third electrode layer 802 and the second electrode layer 702. In some embodiments, the third electrode layer 802 does not have a material composition different than the second electrode layer 702. An interface is nevertheless defined between the third electrode layer 802 and the second electrode layer 702 because the third electrode layer 802 and the second electrode layer 702 are separate, different, etc. layers. In some embodiments, the interface is defined by a discontinuity (e.g., molecular discontinuity, a process-induced discontinuity, etc.) between the third electrode layer 802 and the second electrode layer 702 and/or a difference in at least one of crystallinity, molecular structure, dopant concentration, etc. between the third electrode layer 802 and the second electrode layer 702. In some embodiments, the third electrode layer 802 functions as an anti-reflective coating layer.

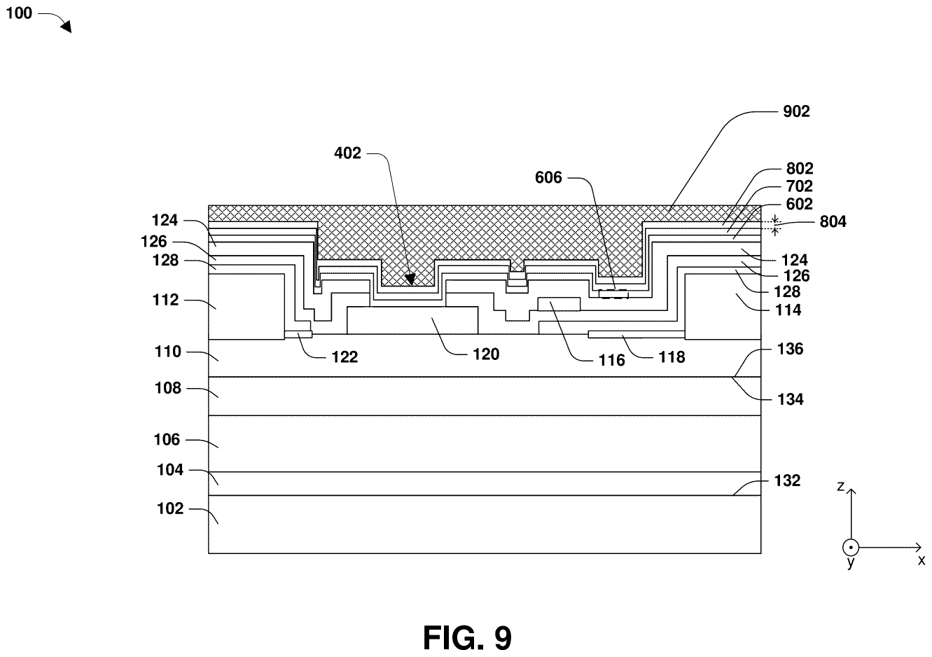

FIG. 9 illustrates a second mask layer 902 formed over the third electrode layer 802, according to some embodiments. The second mask layer 902 at least one of overlies the third electrode layer 802, is in direct contact with a top surface of the third electrode layer 802, or is in indirect contact with the top surface of the third electrode layer 802. The second mask layer 902 is formed by at least one of PVD, sputtering, CVD, PECVD, LPCVD, ALCVD, UHVCVD, RPCVD, ALD, MBE, LPE, spin on, growth, or other suitable techniques. In some embodiments, the second mask layer 902 comprises a light-sensitive material, where properties, such as solubility, of the second mask layer 902 are affected by light. In some embodiments, the second mask layer 902 is a negative photoresist or a positive photoresist.

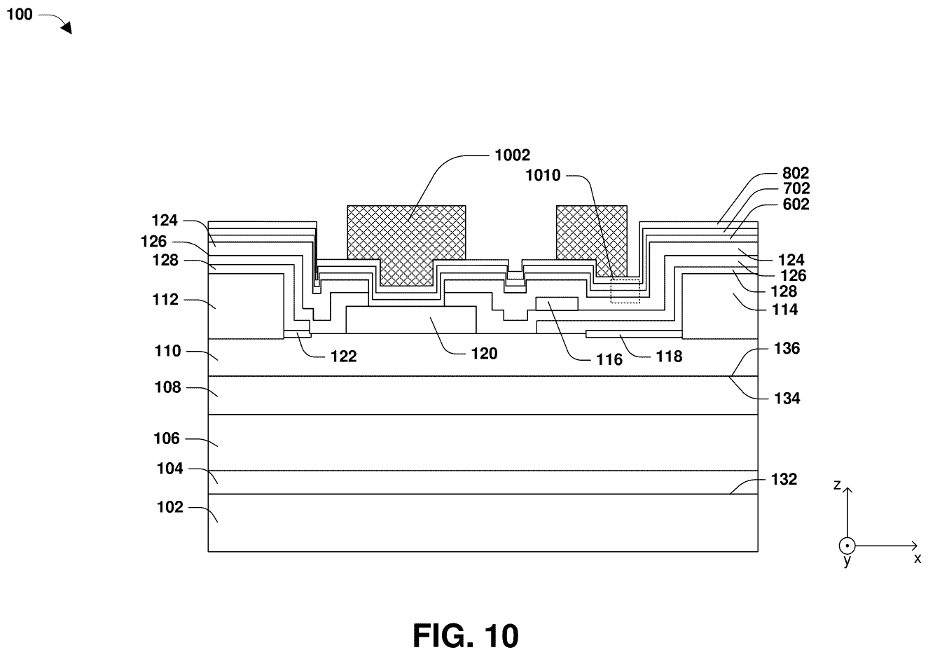

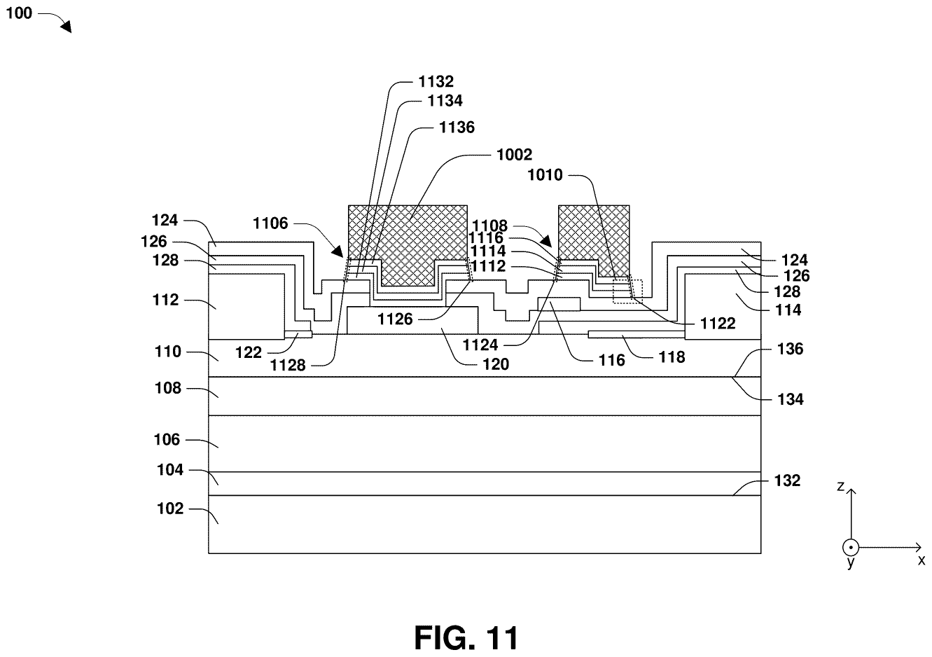

FIG. 10 illustrates a second patterned mask layer 1002 formed from the second mask layer 902, according to some embodiments. FIG. 11 illustrates use of the second patterned mask layer 1002 to pattern one or more second target layers to form a gate electrode 1106 and a gate field plate (GAFP) 1108, according to some embodiments. In some embodiments, the one or more second target layers comprise at least one of the third electrode layer 802, the second electrode layer 702, or the first electrode layer 602. In some embodiments, a second etching process is performed to pattern the one or more second target layers, where the second patterned mask layer 1002 does not cover first portions of the one or more second target layers to allow one or more etchants applied during the second etching process to remove the first portions of one or more second target layers while the second patterned mask layer 1002 protects or shields second portions of the one or more second target layers that are covered by the second patterned mask layer 1002.

In some embodiments, the second etching process comprises a plurality of etching operations comprising at least two of a first etching operation (e.g., main etching operation), a second etching operation (e.g., polymer cleaning operation) after the first second etching operation, or a third etching operation after the second etching operation. In some embodiments, some or all of the plurality of etching operations comprise the same type of etching process, such as at least one of a dry etching process, a wet etching process, an anisotropic etching process, an isotropic etching process, or other suitable etching process. In some embodiments, some or all of the plurality of etching operations comprise reactive ion etching (RIE) processes. In some embodiments, one or more etching chemicals used by the second etching process have an etching selectivity such that the second etching process removes and/or etches away portions of the one or more second target layers while removing and/or etching away little to none of the third dielectric layer 124.

In some embodiments, one, some, or all of the plurality of etching operations are performed while the semiconductor device 100 is in an etching chamber of an etching tool (e.g., single etching tool, such as a RIE tool or other suitable etching tool). In some embodiments, in response to transferring the semiconductor device 100 to the etching chamber, some or all of the plurality of etching operations are performed prior to the semiconductor device 100 being transferred out of the etching chamber. Embodiments are contemplated in which the plurality of etching operations are performed using different etching tools.

In some embodiments, the GAFP 1108 comprises at least one of a first GAFP electrode layer 1112, a second GAFP electrode layer 1114 over the first GAFP electrode layer 1112, or a third GAFP electrode layer 1116 over the second GAFP electrode layer 1114. In some embodiments, at least one of the third GAFP electrode layer 1116 is formed from the third electrode layer 802, the second GAFP electrode layer 1114 is formed from the second electrode layer 702, or the first GAFP electrode layer 1112 is formed from the first electrode layer 602. In some embodiments, the gate electrode 1106 comprises at least one of a first gate electrode layer 1132, a second gate electrode layer 1134 over the first gate electrode layer 1132, or a third gate electrode layer 1136 over the second gate electrode layer 1134. In some embodiments, at least one of the third gate electrode layer 1136 is formed from the third electrode layer 802, the second gate electrode layer 1134 is formed from the second electrode layer 702, or the first gate electrode layer 1132 is formed from the first electrode layer 602.

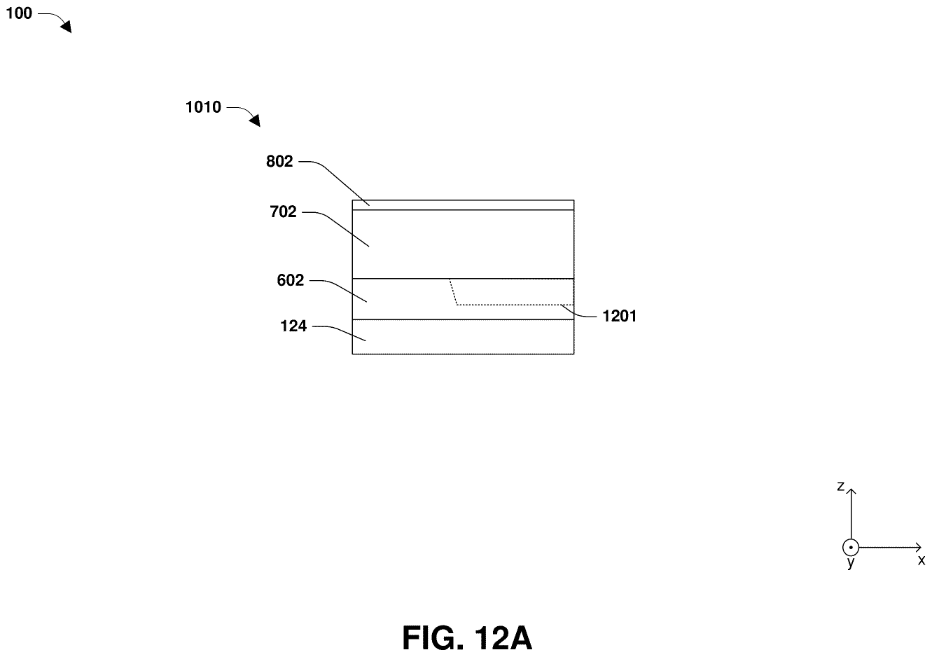

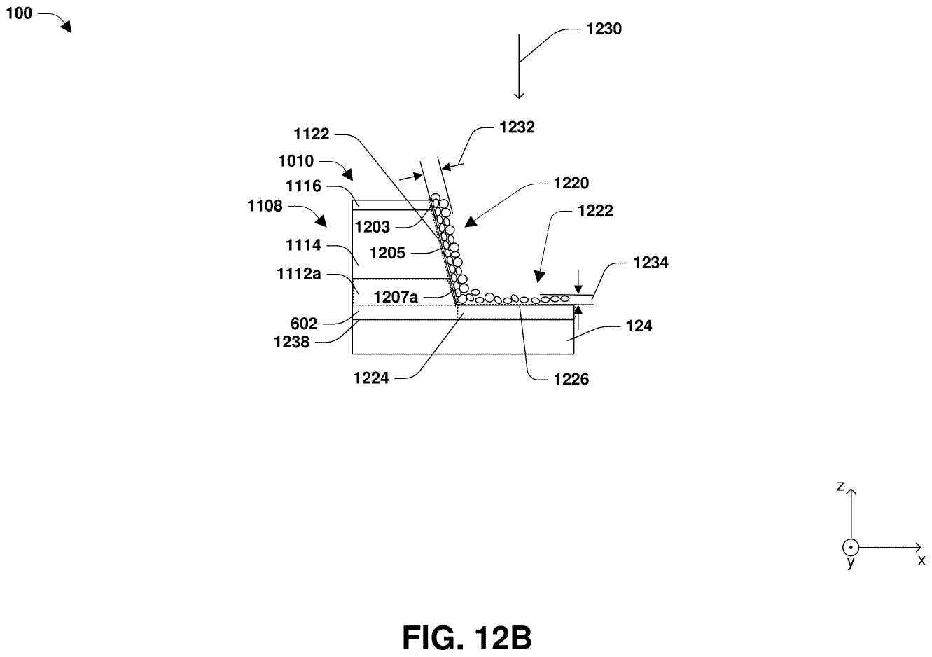

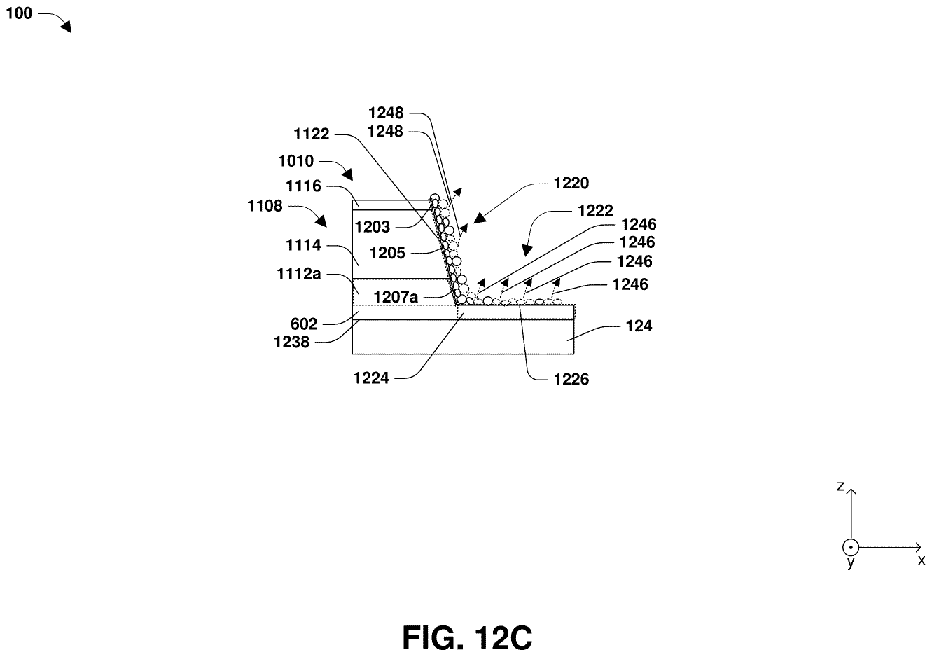

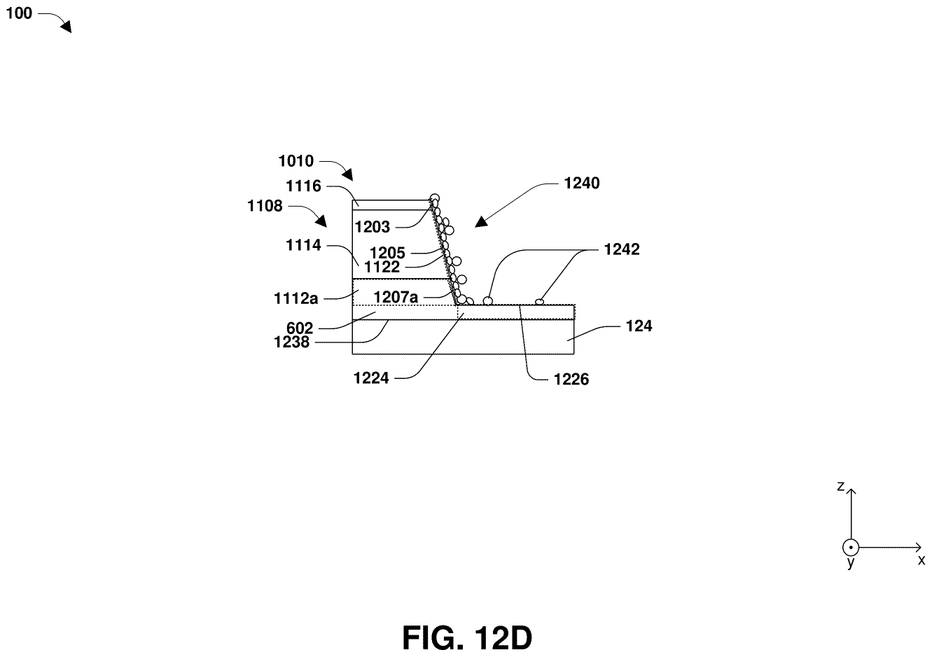

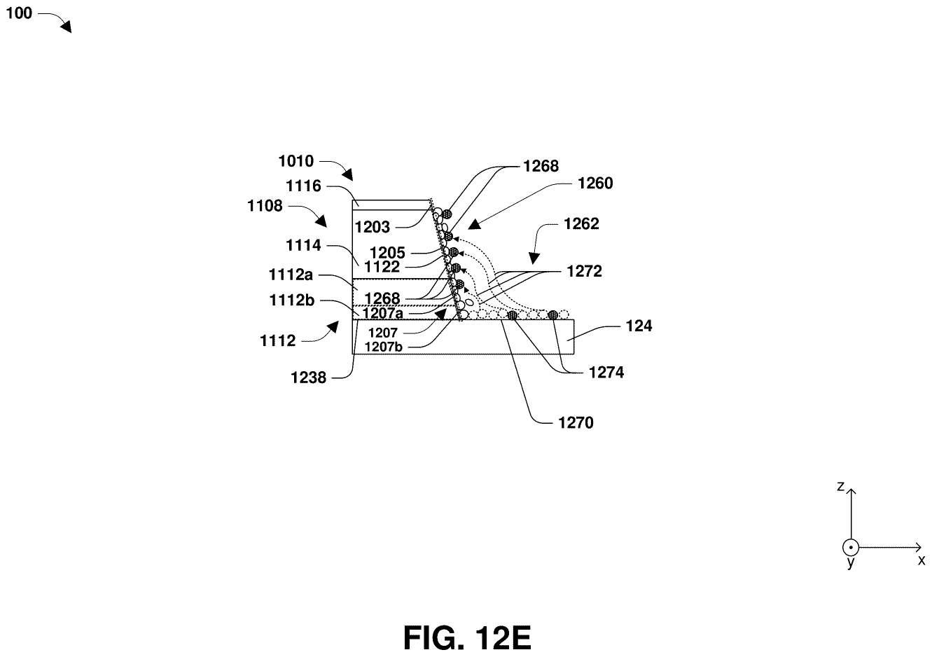

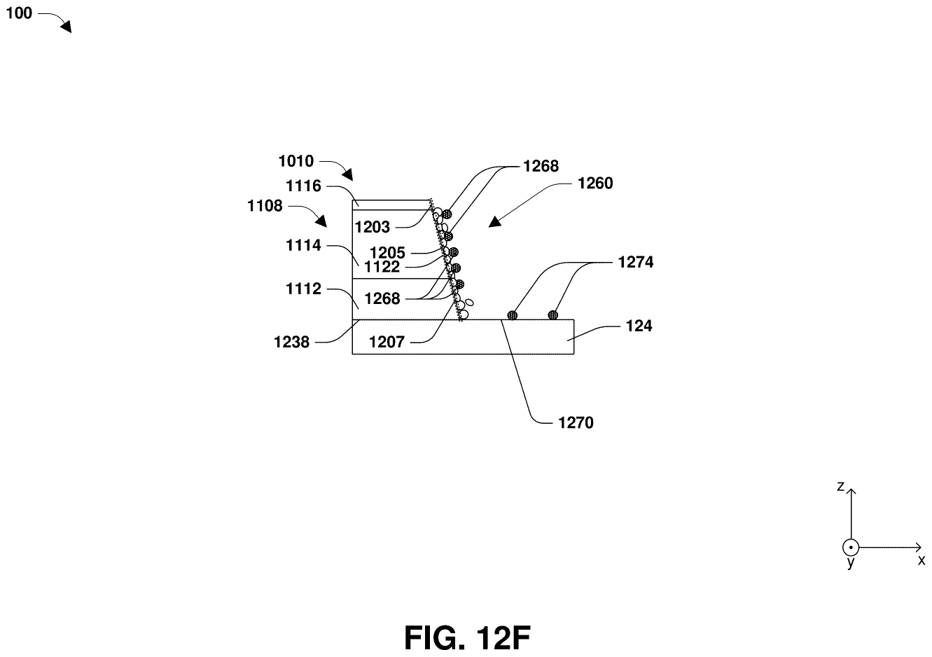

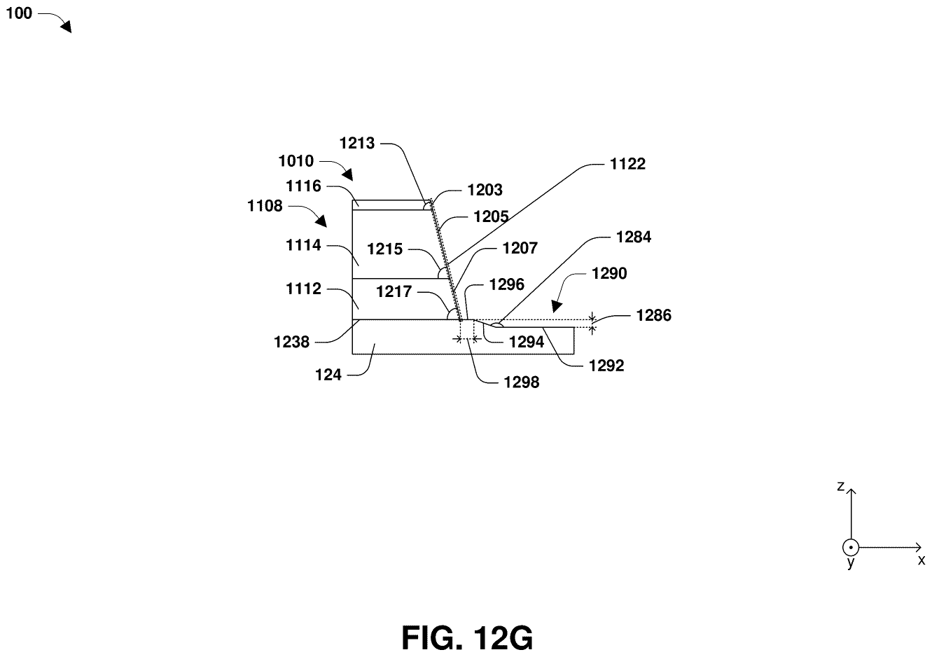

FIGS. 12A-12G illustrate enlarged cross-sectional views of a portion 1010 (shown with a dashed-line outline in FIGS. 10 and 11) of the semiconductor device 100 throughout one or more stages of the second etching process, in accordance with some embodiments. FIG. 12A illustrates the portion 1010 prior to the second etching process, in accordance with some embodiments.

FIG. 12B illustrates the portion 1010 after the first etching operation of the second etching process is performed, in accordance with some embodiments. The first etching operation comprises a first RIE operation. In some embodiments, the first etching operation additionally or alternatively comprises one or more other types of etching operations. In some embodiments, the first etching operation is performed with at least one of a first halogen-containing gas, a first carrier gas, a first RF power, a first ion bombardment direction (e.g., bombardment tilt angle) with which ions are directed to the semiconductor device 100 during the first etching operation, or a first chamber pressure corresponding to a pressure in the etching chamber (in which the semiconductor device 100 undergoes the first etching operation, for example).

In some embodiments, the first etching operation comprises applying the first RF power to an electrode of the etching tool to generate a plasma in the etching chamber from at least one of the first halogen-containing gas or the first carrier gas. In some embodiments, at least one of the first halogen-containing gas or the first carrier gas is dissociated by an electric field created using the first RF power to generate ions of the plasma. In some embodiments, the ions are accelerated toward the semiconductor device 100 at the first ion bombardment direction, such as due at least in part, to a bias voltage induced by the first RF power. In some embodiments, the first ion bombardment direction is impacted by at least one of an orientation of the electric field or the first chamber pressure. In some embodiments, the first ion bombardment direction comprises a direction 1230 or other suitable direction. In some embodiments, the first ion bombardment direction is at least one of perpendicular to a surface 1238 of the third dielectric layer 124 or parallel to a z-axis (shown in FIGS. 1-23).

In some embodiments, the first halogen-containing gas comprises at least one of HF, HCl, HBr, Cl₂, F₂, SF₆, CHF₃, BCl₃, CF₄, or other suitable gas. In some embodiments, the first carrier gas comprises at least one of an inert gas, N₂, Ar, He—O₂, or other suitable gas. The first RF power is at least one of greater than about 300 watts or greater than about 900 watts. Other values of the first RF power are within the scope of the present disclosure. In some embodiments, the first RF power is controlled to control at least one of an ion dissociation rate, an ion bombardment intensity, or an etching rate of the first etching operation. In some embodiments, an increase of the first RF power causes an increase of at least one of the ion dissociation rate, the ion bombardment intensity, or the etching rate of the first etching operation. The first chamber pressure is between about 100 millimillitorr (mmTorr) to about 300 mmTorr. Other values of the first chamber pressure are within the scope of the present disclosure.

In some embodiments, the first etching operation patterns at least one of the third electrode layer 802, the second electrode layer 702, or the first electrode layer 602 to form at least one of the GAFP 1108, the gate electrode 1106, a residual electrode layer 1224 adjacent the GAFP 1108, first byproducts 1220 on the GAFP 1108, or second byproducts 1222 on the residual electrode layer 1224. In some embodiments, the first etching operation removes one or more portions of the third electrode layer 802 to form at least one of the third GAFP electrode layer 1116 or the third gate electrode layer 1136. In some embodiments, the first etching operation removes one or more portions of the second electrode layer 702 to form at least one of the second GAFP electrode layer 1114 or the second gate electrode layer 1134. In some embodiments, the first etching operation removes one or more portions of the first electrode layer 602 to form at least one of the residual electrode layer 1224, at least a portion of the first GAFP electrode layer 1112, or at least a portion of the second gate electrode layer 1134. In some embodiments, the first etching operation removes a first portion 1201 (shown in FIG. 12A) of the first electrode layer 602 to form a first portion 1112a of the first GAFP electrode layer 1112. In some embodiments, the residual electrode layer 1224 comprises a portion, of the first electrode layer 602, that is under the first portion 1201 of the first electrode layer 602 that is removed by the first etching operation. In some embodiments, the first byproducts 1220 are disposed upon a first sidewall 1122 of the GAFP 1108. In some embodiments, the second byproducts 1222 are disposed upon a surface 1226 (e.g., top surface) of the residual electrode layer 1224. In some embodiments, the first sidewall 1122 of the GAFP 1108 comprises a sidewall 1203 of the third GAFP electrode layer 1116, a sidewall 1205 of the second GAFP electrode layer 1114, or a sidewall 1207a of the first portion 1112a of the first GAFP electrode layer 1112.

In some embodiments, the first byproducts 1220 comprise first polymer byproducts. In some embodiments, the first polymer byproducts comprise at least one of carbon-based polymers, metal-based polymers, or one or more other types of polymers. In some embodiments, the first byproducts 1220 comprise first metal byproducts, such as at least one of TiN, Ti, TiW, TaN, TiAlN, TaAlN, HfN, AlCu, Co, Al, Cu, Mo, Ru, W, Ta, TiW, SiN, SiO₂, Al₂O₃, AlN, TaN, TiAlN, or other metal. In some embodiments, the first byproducts 1220 (e.g., the first polymer byproducts) comprise residue from the second mask layer 902 (e.g., photoresist), such as material transferred from the second patterned mask layer 1002 (e.g., patterned photoresist) to the first sidewall 1122 of the GAFP 1108 during the first etching operation. In some embodiments, the first byproducts 1220 (e.g., the first metal byproducts and/or the first polymer byproducts) comprise residue from at least one of the first electrode layer 602, the second electrode layer 702, or the third electrode layer 802, such as material transferred from at least one of the first electrode layer 602, the second electrode layer 702, or the third electrode layer 802 to the first sidewall 1122 of the GAFP 1108 during the first etching operation. In some embodiments, the first byproducts 1220 (e.g., the first polymer byproducts) comprise residue from an etching gas (e.g., at least one of the first halogen-containing gas or the first carrier gas) used by the first etching operation. In some embodiments, the first byproducts 1220 (e.g., the first polymer byproducts) comprise residue from the etching tool, such as residue from a chamber wall that defines the etching chamber. In some embodiments, the first byproducts 1220 (e.g., the first metal byproducts and/or the first polymer byproducts) comprise one or more products of one or more chemical reactions induced by the first etching operation, such as one or more reactions between an etching gas (e.g., at least one of the first halogen-containing gas or the first carrier gas) used by the first etching operation and at least one of the first electrode layer 602, the second electrode layer 702, or the third electrode layer 802. In some embodiments, the first byproducts 1220 (e.g., the first metal byproducts and/or the first polymer byproducts) comprise solid materials that remain on the first sidewall 1122 of the GAFP 1108 after the first etching operation is performed, such as due, at least in part, to a volatility of the solid materials being less than a threshold volatility.

In some embodiments, the second byproducts 1222 comprise second polymer byproducts. In some embodiments, the second polymer byproducts comprise at least one of carbon-based polymers, metal-based polymers, or one or more other types of polymers. In some embodiments, the second byproducts 1222 comprise second metal byproducts, such as at least one of TiN, Ti, TiW, TaN, TiAlN, TaAlN, HfN, AlCu, Co, Al, Cu, Mo, Ru, W, Ta, TiW, SiN, SiO₂, Al₂O₃, AlN, TaN, TiAlN, or other metal. In some embodiments, the second byproducts 1222 (e.g., the second polymer byproducts) comprise residue from the second mask layer 902 (e.g., photoresist), such as material transferred from the second patterned mask layer 1002 (e.g., patterned photoresist) to the surface 1226 of the residual electrode layer 1224 during the first etching operation. In some embodiments, the second byproducts 1222 (e.g., the second metal byproducts and/or the second polymer byproducts) comprise residue from at least one of the first electrode layer 602, the second electrode layer 702, or the third electrode layer 802, such as material transferred from at least one of the first electrode layer 602, the second electrode layer 702, or the third electrode layer 802 to the surface 1226 of the residual electrode layer 1224 during the first etching operation. In some embodiments, the second byproducts 1222 (e.g., the second polymer byproducts) comprise residue from an etching gas (e.g., at least one of the first halogen-containing gas or the first carrier gas) used by the first etching operation. In some embodiments, the second byproducts 1222 (e.g., the second polymer byproducts) comprise residue from the etching tool, such as residue from a chamber wall that defines a chamber (e.g., the etching chamber) in which the semiconductor device 100 undergoes the first etching operation. In some embodiments, the second byproducts 1222 (e.g., the second metal byproducts and/or the second polymer byproducts) comprise one or more products of one or more chemical reactions induced by the first etching operation, such as one or more reactions between an etching gas (e.g., at least one of the first halogen-containing gas or the first carrier gas) used by the first etching operation and at least one of the first electrode layer 602, the second electrode layer 702, or the third electrode layer 802. In some embodiments, the second byproducts 1222 (e.g., the second metal byproducts and/or the second polymer byproducts) comprise solid materials that remain on the surface 1226 of the residual electrode layer 1224 after the first etching operation is performed, such as due, at least in part, to a volatility of the solid materials being less than a threshold volatility.

In some embodiments, the first etching operation is performed such that a first thickness 1232 of the first byproducts 1220 on the GAFP 1108 is greater than a second thickness 1234 of the second byproducts 1222 on the residual electrode layer 1224. A ratio of the first thickness 1232 of the first byproducts 1220 on the GAFP 1108 to the second thickness 1234 of the second byproducts 1222 on the residual electrode layer 1224 is at least one of between about 1.5:1 to about 6.5:1, or between about 3.5:1 to about 4.5:1. Other values of the ratio are within the scope of the present disclosure. In some embodiments, the first thickness 1232 is greater than the second thickness 1234 due, at least in part, to a first ion bombardment intensity of the first etching operation at the first sidewall 1122 of the GAFP 1108 being less than a second ion bombardment intensity of the first etching operation at the surface 1226 of the residual electrode layer 1224. In some embodiments, the first ion bombardment intensity at the first sidewall 1122 is less than the second bombardment intensity during the first etching operation due to more ions being directed along the first ion bombardment direction towards one or more horizontal surfaces (e.g., the surface 1226 of the residual electrode layer 1224) of the semiconductor device 100 than to one or more vertical and/or tapered surfaces (e.g., the first sidewall 1122) of the semiconductor device 100. In some embodiments, the first ion bombardment intensity of the first etching operation at the first sidewall 1122 of the GAFP 1108 being less than the second ion bombardment intensity of the first etching operation at the surface 1226 of the residual electrode layer 1224 results in more efficient removal of byproducts on the surface 1226 of the residual electrode layer 1224 than on the first sidewall 1122 of the GAFP 1108 such that the first thickness 1232 is greater than the second thickness 1234.

In some embodiments, the first thickness 1232 of the first byproducts 1220 on the GAFP 1108 is greater than the second thickness 1234 of the second byproducts 1222 on the residual electrode layer 1224 due, at least in part, to a first chemical reactivity at the first sidewall 1122 of the GAFP 1108 being less than a second chemical reactivity at the surface 1226 of the residual electrode layer 1224. In some embodiments, the first chemical reactivity at the first sidewall 1122 being less than the second chemical reactivity at the surface 1226 causes byproducts to be removed at a greater speed, such as immediately upon formation, at the surface 1226 of the residual electrode layer 1224 as compared with the first sidewall 1122 of the GAFP 1108, thereby providing for a greater amount of byproducts to accumulate on the first sidewall 1122 of the GAFP 1108 without being removed than on the surface 1226 of the residual electrode layer 1224.

In some embodiments, the first thickness 1232 of the first byproducts 1220 on the GAFP 1108 is greater than the second thickness 1234 of the second byproducts 1222 on the residual electrode layer 1224 due, at least in part, to byproducts formed from the second patterned mask layer 1002 (e.g., photoresist material) being deposited at a greater rate on the first sidewall 1122 of the GAFP 1108 than on the surface 1226 of the residual electrode layer 1224. In some embodiments, the greater rate on the first sidewall 1122 than on the surface 1226 is due to at least one of a composition of the first carrier gas, a composition of the first carrier gas, the first etching pressure, or the first RF power. In some embodiments, byproducts formed from the second patterned mask layer 1002 form a first local hard mask on the first sidewall 1122. In some embodiments, the first byproducts 1220 comprise the first local hard mask.

FIGS. 12C-12D illustrate aspects of the second etching operation, in accordance with some embodiments. In some embodiments, the second etching operation is performed in response to performing the first etching operation. The second etching operation comprises a second RIE operation. In some embodiments, the second etching operation additionally or alternatively comprises one or more other types of etching operations.

FIG. 12C illustrates the portion 1010 while the second etching operation of the second etching process is performed, in accordance with some embodiments. FIG. 12D illustrates the portion 1010 after the second etching operation is performed, in accordance with some embodiments. In some embodiments, the second etching operation is performed with at least one of a second etching gas, a second RF power, a second ion bombardment direction (e.g., bombardment tilt angle) with which ions are directed to the semiconductor device 100 during the second etching operation, or a second chamber pressure corresponding to a pressure in the etching chamber (in which the semiconductor device 100 undergoes the second etching operation, for example).

In some embodiments, the second etching operation comprises applying the second RF power to an electrode of the etching tool to generate a plasma in the etching chamber from the second etching gas. In some embodiments, the second etching gas is dissociated by an electric field created using the second RF power to generate ions of the plasma. In some embodiments, the ions are accelerated toward the semiconductor device 100 at the second bombardment direction, such as due at least in part, to a bias voltage induced by the second RF power. In some embodiments, the second ion bombardment direction is impacted by at least one of an orientation of the electric field or the second chamber pressure. In some embodiments, the second ion bombardment direction comprises the direction 1230 (shown in FIG. 12B) or other suitable direction. In some embodiments, the second ion bombardment direction is at least one of perpendicular to the surface 1238 of the third dielectric layer 124 or parallel to the z-axis.

In some embodiments, the second etching gas comprises at least one of N2, Ar, H—O2, HF, HCl, HBr, Cl₂, F₂, SF₆, CHF₃, BCl₃, CF₄, or other suitable gas. The second RF power is between about 300 watts to about 900 watts. Other values of the second RF power are within the scope of the present disclosure. In some embodiments, the second RF power is less than the first RF power. In some embodiments, the second RF power is controlled to control at least one of an ion dissociation rate, an ion bombardment intensity, or an etching rate of the second etching operation. An etching rate of an electrode layer (e.g., at least one of the residual electrode layer 1224 or the first electrode layer 602) during the second etching operation is less than about 500 angstroms per minute. Other values of the etching rate are within the scope of the present disclosure. In some embodiments, an increase of the second RF power causes an increase of at least one of the ion dissociation rate, the ion bombardment intensity, or the etching rate of the second etching operation. In some embodiments, the second chamber pressure is less than the first chamber pressure. The second chamber pressure is between about 1 mmTorr to about 100 mmTorr. Other values of the first chamber pressure are within the scope of the present disclosure. In some embodiments, the second chamber pressure being between about 1 mmTorr to about 100 mmTorr facilitates physical bombardment in the second etching operation. In some embodiments, the second chamber pressure is less than the first chamber pressure.

In some embodiments, the second etching gas has an etching selectivity such that the second etching process removes and/or etches away the second byproducts 1222 while removing and/or etching away little to none of at least one of the residual electrode layer 1224. In some embodiments, the second etching operation removes a first portion of the first byproducts 1220 from the GAFP 1108, wherein a second portion 1240 (shown in FIG. 12D) of the first byproducts 1220 remains on the GAFP 1108 (e.g., on the first sidewall 1122 of the GAFP 1108) after the second etching operation. In FIG. 12C, byproducts of the first portion of the first byproducts 1220 (that are removed during the second etching operation) are shown as dotted-line objects and byproducts of the second portion 1240 of the first byproducts 1220 (that are remain on the GAFP 1108 after the second etching operation) are shown as solid-line objects, in accordance with some embodiments. In some embodiments, the first portion of the first byproducts 1220 is removed from the first sidewall 1122 of the GAFP 1108 along one or more paths 1248 (shown as dashed-line arrows in FIG. 12C) and/or one or more other paths. In some embodiments, the second etching operation is performed such that at most a first threshold proportion of the first byproducts 1220 is removed from the first sidewall 1122 of the GAFP 1108 (e.g., the first portion of the first byproducts 1220 that is removed during the second etching operation makes up at most the first threshold proportion of the first byproducts 1220). The first threshold proportion is between about 0% to about 50%. Other values of the first threshold proportion are within the scope of the present disclosure. In some embodiments, the second etching operation is performed such that at least a second threshold proportion of the first sidewall 1122 of the GAFP 1108 is covered by the second portion 1240 of the first byproducts 1220 that remain on the first sidewall 1122 of the GAFP 1108 after the second etching operation. The second threshold proportion is between about 80% to about 100%. Other values of the second threshold proportion are within the scope of the present disclosure. In some embodiments, the second portion 1240 of the first byproducts 1220 forms a second local hard mask on the first sidewall 1122 that protects the first sidewall 1122 during one or more subsequent etching operations.

In some embodiments, the second etching operation removes the second byproducts 1222 from the residual electrode layer 1224. In some embodiments, the second byproducts 1222 are removed from the residual electrode layer 1224 along one or more paths 1246 (shown as dashed-line arrows in FIG. 12C) and/or one or more other paths. In some embodiments, the second etching operation removes merely a first portion of the second byproducts 1222 from the residual electrode layer 1224, wherein a second portion 1242 (shown in FIG. 12D) of the second byproducts 1222 remains on the residual electrode layer 1224 after the second etching operation. In some embodiments, the second etching operation is performed such that a first rate of removal of the first byproducts 1220 per unit length along the first sidewall 1122 of the GAFP 1108 during the second etching operation is less than a second rate of removal of the second byproducts 1222 per unit length along the surface 1226 of the residual electrode layer 1224 during the second etching operation.

In FIG. 12C, byproducts of the first portion of the second byproducts 1222 (that are removed during the second etching operation) are shown as dotted-line objects and byproducts of the second portion 1242 of the second byproducts 1222 (that are remain on the residual electrode layer 1224 after the second etching operation) are shown as solid-line objects, in accordance with some embodiments. In some embodiments, the second etching operation is performed such that at least a third threshold proportion of the second byproducts 1222 is removed from the residual electrode layer 1224. The third threshold proportion is between about 50% to about 100%. Other values of the third threshold proportion are within the scope of the present disclosure. In some embodiments, the second etching operation is performed such that at most a fourth threshold proportion of the surface 1226 of the residual electrode layer 1224 is covered by the second portion 1242 of the second byproducts 1222 that remain on the residual electrode layer 1224 after the second etching operation (to allow subsequent etching of the residual electrode layer 1224, for example). The fourth threshold proportion is between about 0% to about 20%. Other values of the fourth threshold proportion are within the scope of the present disclosure. Embodiments are contemplated in which the second etching operation removes all of the second byproducts 1222.

In some embodiments, one or more results (e.g., at least one of the first rate of removal of the first byproducts 1220 on the first sidewall 1122 being less than the second rate of removal of the second byproducts 1222 on the residual electrode layer 1224, at most the first threshold proportion of the first byproducts 1220 being removed from the first sidewall 1122 of the GAFP 1108 to leave the second portion 1240 of the first byproducts 1220, the second portion 1240 of the first byproducts 1220 covering at least the second threshold proportion of the first sidewall 1122 of the GAFP 1108, at least the third threshold proportion of the second byproducts 1222 being removed from the residual electrode layer 1224 to remove all of the second byproducts 1222 or to leave the second portion 1242 of the second byproducts 1222, the second portion 1242 of the second byproducts 1222 covering at most the fourth threshold proportion of the surface 1226 of the residual electrode layer 1224, the second local hard mask being formed on the first sidewall 1122 to protect the first sidewall 1122, or one or more other results) achieved by the second etching operation are due, at least in part, to a first processing time of the second etching operation (e.g., a duration of time that the semiconductor device 100 is exposed to plasma and/or etchants in the second etching operation) being less than a first threshold processing time, the first thickness 1232 of the first byproducts 1220 on the GAFP 1108 being greater than the second thickness 1234 of the second byproducts 1222 on the residual electrode layer 1224, the second chamber pressure being between about 1 mmTorr to about 100 mmTorr, or increased dominance of physical bombardment and/or reduced dominance of chemical interaction in the second etching operation (which is facilitated by setting the second chamber pressure to be between about 1 mmTorr to about 100 mmTorr, for example).

Configuring the first processing time of the second etching operation to be less than the first threshold processing time provides for removing the second byproducts 1222 from the residual electrode layer 1224 while leaving the second portion 1240 of the first byproducts 1220 (e.g., the second local hard mask) on the first sidewall 1122 of the GAFP 1108, whereas setting the first processing time to a duration of time that is greater than the first threshold processing time may result in the second portion 1240 of the first byproducts 1220 being removed during the etching operation, thereby leaving the first sidewall 1122 of the GAFP 1108 unprotected after the second etching operation.

In some embodiments, the third etching operation is performed in response to performing the second etching operation. In some embodiments, the third etching operation is performed to remove the residual electrode layer 1224. In some embodiments, removing the residual electrode layer 1224 extends the first sidewall 1122 of the GAFP 1108 such that the first sidewall 1122 is adjacent to or meets the third dielectric layer 124. In some embodiments, the third etching operation comprises a multi-stage operation comprising a first etching stage (e.g., high polymerization operation) and a second etching stage (e.g., over etching operation).

FIGS. 12E-12F illustrate aspects of the first etching stage, in accordance with some embodiments. In some embodiments, the first etching stage is performed in response to performing the second etching operation. The first etching stage comprises a third RIE operation. In some embodiments, the first etching stage additionally or alternatively comprises one or more other types of etching operations.

FIG. 12E illustrates the portion 1010 while the first etching stage of the third etching operation is performed, in accordance with some embodiments. FIG. 12F illustrates the portion 1010 after the first etching stage is performed, in accordance with some embodiments. In some embodiments, the first etching stage is performed with at least one of a second halogen-containing gas, a second carrier gas, a third RF power, a third ion bombardment direction (e.g., bombardment tilt angle) with which ions are directed to the semiconductor device 100 during the first etching stage, or a third chamber pressure corresponding to a pressure in the etching chamber (in which the semiconductor device 100 undergoes the first etching stage, for example).

In some embodiments, the first etching stage comprises supplying the second halogen-containing gas and the second carrier gas into the etching chamber. In some embodiments, the first etching stage comprises applying the third RF power to an electrode of the etching tool to generate a plasma in the etching chamber from at least one of the second halogen-containing gas or the second carrier gas. In some embodiments, at least one of the second halogen-containing gas or the second carrier gas is dissociated by an electric field created using the third RF power to generate ions of the plasma. In some embodiments, the ions are accelerated toward the semiconductor device 100 at the third ion bombardment direction, such as due at least in part, to a bias voltage induced by the third RF power. In some embodiments, the third ion bombardment direction is impacted by at least one of an orientation of the electric field or the third chamber pressure. In some embodiments, the third ion bombardment direction comprises the direction 1230 (shown in FIG. 12B) or other suitable direction. In some embodiments, the third ion bombardment direction is at least one of perpendicular to the surface 1238 of the third dielectric layer 124 or parallel to the z-axis.

In some embodiments, the second halogen-containing gas comprises at least one of HF, HCl, HBr, Cl₂, F₂, SF₆, CHF₃, BCl₃, CF₄, or other suitable gas. In some embodiments, the second carrier gas comprises at least one of an inert gas, N₂, Ar, He—O₂, or other suitable gas. In some embodiments, the second halogen-containing gas used by the first etching stage of the third etching operation is the same as the first halogen-containing gas used by the first etching operation. The third RF power is between about 300 watts to about 900 watts. Other values of the third RF power are within the scope of the present disclosure. In some embodiments, the third RF power is about equal to the second RF power. In some embodiments, the third RF power is less than the first RF power. In some embodiments, the third RF power is controlled to control at least one of an ion dissociation rate, an ion bombardment intensity, or an etching rate of the first etching stage. In some embodiments, an increase of the third RF power causes an increase of at least one of the ion dissociation rate, the ion bombardment intensity, or the etching rate of the first etching stage. In some embodiments, the third chamber pressure is less than the first chamber pressure. The third chamber pressure is between about 1 mmTorr to about 100 mmTorr. Other values of the third chamber pressure are within the scope of the present disclosure. In some embodiments, the third chamber pressure is about equal to the second chamber pressure.

In some embodiments, the first etching stage removes the residual electrode layer 1224 to extend the first sidewall 1122 of the GAFP 1108 to meet the third dielectric layer 124 and to expose a portion 1270 (shown in FIGS. 12E and 12F) of the third dielectric layer 124. In some embodiments, removing the residual electrode layer 1224 forms a second portion 1112b of the first GAFP electrode layer 1112 (shown in FIG. 12E). In some embodiments, the first sidewall 1122 of the GAFP 1108 comprises a sidewall 1207b (shown in FIG. 12E) of the second portion 1112b of the first GAFP electrode layer 1112. Accordingly, the first GAFP electrode layer 1112 of the GAFP 1108 has a sidewall 1207 comprising the sidewall 1207a of the first portion 1112a of the first GAFP electrode layer 1112 and the sidewall 1207b of the second portion 1112b of the first GAFP electrode layer 1112, in accordance with some embodiments.

In some embodiments, third byproducts 1260 (shown in FIGS. 12E and 12F) remain on the first sidewall 1122 after the first etching stage. In some embodiments, the third byproducts 1260 comprise an amount (e.g., some or all) of the second portion 1240 (shown in FIG. 12D) of the first byproducts 1220 that remained on the GAFP 1108 after the second etching operation. In some embodiments, the third byproducts 1260 comprise third polymer byproducts 1268 (shown as pattern-filled objects in FIGS. 12E and 12F). In some embodiments, the third byproducts 1260 form a third local hard mask on the first sidewall 1122 that protects the first sidewall 1122 during one or more subsequent etching operations.

In some embodiments, the third polymer byproducts 1268 comprise at least one of carbon-based polymers, metal-based polymers, or one or more other types of polymers. In some embodiments, the third polymer byproducts 1268 comprise residue from the second mask layer 902 (e.g., photoresist), such as material transferred from the second patterned mask layer 1002 (e.g., patterned photoresist) to the first sidewall 1122 of the GAFP 1108 during the first etching stage of the third etching operation. In some embodiments, the third polymer byproducts 1268 comprise residue from an etching gas (e.g., at least one of the second halogen-containing gas or the second carrier gas) used by the first etching stage of the third etching operation. In some embodiments, the third polymer byproducts 1268 comprise residue from the etching tool, such as residue from a chamber wall that defines the etching chamber. In some embodiments, the third polymer byproducts 1268 comprise one or more products of one or more chemical reactions induced by the first etching stage of the third etching operation, such as one or more reactions between an etching gas (e.g., at least one of the second halogen-containing gas or the second carrier gas) used by the first etching stage of the third etching operation and at least one of the residual electrode layer 1224 or the third dielectric layer 124. In some embodiments, the third polymer byproducts 1268 comprise solid materials that remain on the first sidewall 1122 of the GAFP 1108 after the first etching stage of the third etching operation is performed, such as due, at least in part, to a volatility of the solid materials being less than a threshold volatility. In some embodiments, the third polymer byproducts 1268 do not comprise metals.

In some embodiments, fourth polymer byproducts 1262 (shown in FIG. 12E) are formed on the third dielectric layer 124 during the first etching stage. In some embodiments, the fourth polymer byproducts 1262 comprise at least one of carbon-based polymers, metal-based polymers, or one or more other types of polymers. In some embodiments, the fourth polymer byproducts 1262 comprise residue from the second mask layer 902 (e.g., photoresist), such as material transferred from the second patterned mask layer 1002 (e.g., patterned photoresist) to the third dielectric layer 124 during the first etching stage of the third etching operation. In some embodiments, the fourth polymer byproducts 1262 comprise residue from an etching gas (e.g., at least one of the second halogen-containing gas or the second carrier gas) used by the first etching stage of the third etching operation. In some embodiments, the fourth polymer byproducts 1262 comprise residue from the etching tool, such as residue from a chamber wall that defines the etching chamber. In some embodiments, the fourth polymer byproducts 1262 comprise one or more products of one or more chemical reactions induced by the first etching stage of the third etching operation, such as one or more reactions between an etching gas (e.g., at least one of the second halogen-containing gas or the second carrier gas) used by the first etching stage of the third etching operation and at least one of the residual electrode layer 1224 or the third dielectric layer 124. In some embodiments, the fourth polymer byproducts 1262 do not comprise metals.

In some embodiments, fifth polymer byproducts of the fourth polymer byproducts 1262 are removed from the third dielectric layer 124 during the first etching stage of the third etching operation. In some embodiments, the fifth polymer byproducts comprise some or all of the fourth polymer byproducts 1262. In some embodiments, some or all of the fifth polymer byproducts are transferred to the first sidewall 1122 of the GAFP 1108 along one or more paths 1272 (shown as dashed-line arrows in FIG. 12E) and/or one or more other paths. In some embodiments, the fourth polymer byproducts 1262 comprise sixth polymer byproducts 1274 (shown in FIGS. 12E and 12F) that remain on the third dielectric layer 124 after the first etching stage. In FIG. 12E, the fifth polymer byproducts (that are removed from the third dielectric layer 124 and/or transferred to the first sidewall 1122 of the GAFP 1108 or other location during the first etching stage) are shown as dotted-line white-filled objects, and the sixth polymer byproducts 1274 are shown as solid-line pattern-filled objects.

In some embodiments, the first etching stage of the third etching operation is performed such that at most a fifth threshold proportion of a surface of the (exposed) portion 1270 of the third dielectric layer 124 is covered by the sixth polymer byproducts 1274 (shown in FIGS. 12E and 12F) that remain on the third dielectric layer 124 after the first etching stage (to allow subsequent etching of the third dielectric layer 124, for example). The fifth threshold proportion is between about 0% to about 20%. Other values of the fifth threshold proportion are within the scope of the present disclosure.

In some embodiments, the second etching stage of the third etching operation is performed in response to performing the first etching stage of the third etching operation. FIG. 12G illustrates the portion 1010 after the second etching stage of the third etching operation is performed, in accordance with some embodiments. In some embodiments, the second etching stage is performed with at least one of a third halogen-containing gas, a third carrier gas, a fourth RF power, a fourth ion bombardment direction (e.g., bombardment tilt angle) with which ions are directed to the semiconductor device 100 during the second etching stage, or a fourth chamber pressure corresponding to a pressure in the etching chamber (in which the semiconductor device 100 undergoes the second etching stage, for example).

In some embodiments, the second etching stage comprises supplying the third halogen-containing gas and the third carrier gas into the etching chamber. In some embodiments, a first flow rate ratio of the second halogen-containing gas to the second carrier gas supplied to the etching chamber during the first etching stage is greater than a second flow rate ratio of the third halogen-containing gas to the third carrier gas supplied to the etching chamber during the first etching stage. In some embodiments, the first flow rate ratio is between about 2 times the second flow rate ratio to about 3 times the second flow rate ratio. In some embodiments, the second etching stage comprises applying the fourth RF power to an electrode of the etching tool to generate a plasma in the etching chamber from at least one of the third halogen-containing gas or the third carrier gas. In some embodiments, at least one of the third halogen-containing gas or the third carrier gas is dissociated by an electric field created using the fourth RF power to generate ions of the plasma. In some embodiments, the ions are accelerated toward the semiconductor device 100 at the fourth ion bombardment direction, such as due at least in part, to a bias voltage induced by the fourth RF power. In some embodiments, the fourth ion bombardment direction is impacted by at least one of an orientation of the electric field or the fourth chamber pressure. In some embodiments, the fourth ion bombardment direction comprises the direction 1230 (shown in FIG. 12B) or other suitable direction. In some embodiments, the fourth ion bombardment direction is at least one of perpendicular to the surface 1238 of the third dielectric layer 124 or parallel to the z-axis.

In some embodiments, the third halogen-containing gas comprises at least one of HF, HCl, HBr, Cl₂, F₂, SF₆, CHF₃, BCl₃, CF₄, or other suitable gas. In some embodiments, the third carrier gas comprises at least one of an inert gas, N₂, Ar, He—O₂, or other suitable gas. In some embodiments, the third halogen-containing gas used by the second etching stage of the third etching operation is the same as at least one of the first halogen-containing gas used by the first etching operation or the second halogen-containing gas used by the first etching stage of the third etching operation. The fourth RF power is at least one of less than about 900 watts or less than about 300 watts. Other values of the fourth RF power are within the scope of the present disclosure. In some embodiments, the fourth RF power is less than at least one of the first RF power, the second RF power, or the third RF power. A ratio of the third RF power to the fourth RF power is between about 2:1 to about 4:1. Other values of the ratio are within the scope of the present disclosure. In some embodiments, the fourth RF power is controlled to control at least one of an ion dissociation rate, an ion bombardment intensity, or an etching rate of the second etching stage. In some embodiments, an increase of the fourth RF power causes an increase of at least one of the ion dissociation rate, the ion bombardment intensity, or the etching rate of the second etching stage.

In some embodiments, the fourth chamber pressure is less than the first chamber pressure. The fourth chamber pressure is between about 1 mmTorr to about 100 mmTorr. Other values of the fourth chamber pressure are within the scope of the present disclosure. In some embodiments, the fourth chamber pressure is about equal to at least one of the second chamber pressure or the third chamber pressure.

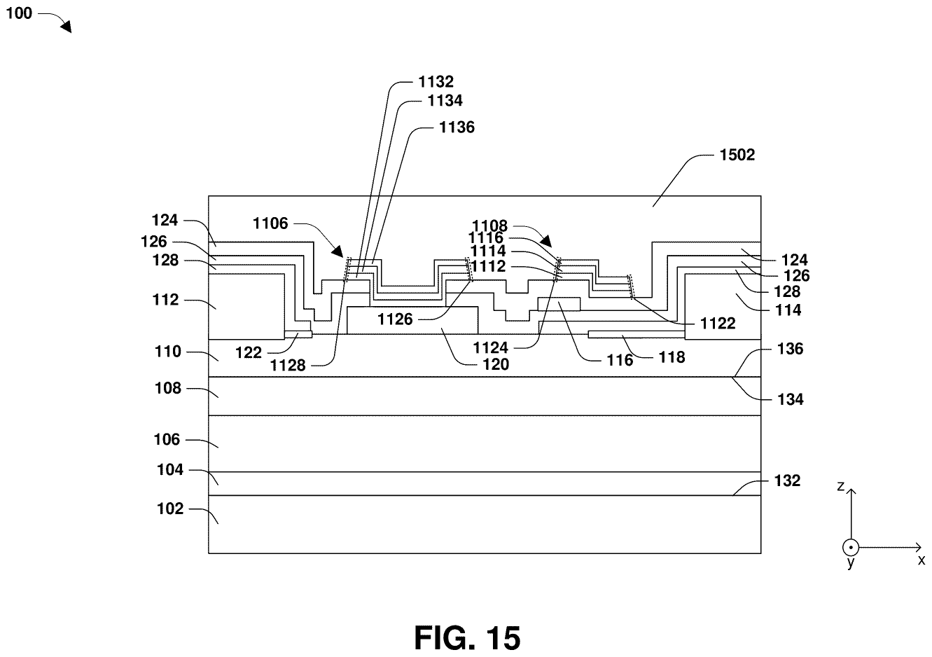

In some embodiments, the second etching stage removes at least one of the third byproducts 1260, the sixth polymer byproducts 1274, or other byproducts such as metal residue on the third dielectric layer 124. In some embodiments, the second etching stage removes the portion 1270 (shown in FIGS. 12E and 12F) of the third dielectric layer 124 to form a recess 1290 in the third dielectric layer 124. In some embodiments, the recess 1290 is defined by a surface 1292 of the third dielectric layer 124 and a sidewall 1294 of the third dielectric layer 124 extending from the surface 1292 to a dielectric platform 1298 of the third dielectric layer 124. In some embodiments, the sidewall 1294 is tapered. An angle of extension 1284 of the sidewall 1294 relative to at least one of the surface 1292, the surface 1238, or the x-axis is between about 120 degrees to about 160 degrees. A depth 1286 (e.g., maximum depth) of the recess 1290 is between about 200 angstroms to about 500 angstroms. Other values of the angle of extension 1284 and the depth 1286 are within the scope of the present disclosure. In some embodiments, the recess 1290 is formed such that the depth 1286 is not greater than a threshold depth (e.g., 500 angstroms) that is associated with insufficient breakdown voltage. In some embodiments, forming the recess 1290 to have the depth 1286 between about 200 angstroms to about 500 angstroms provides for increased breakdown voltage of the semiconductor device 100 as compared with forming the recess 1290 to have a depth greater than about 500 angstroms, such as due, at least in part, to a dielectric constant of the third dielectric layer 124 being greater than a dielectric constant of a dielectric layer, such as fourth dielectric layer 1502 shown in FIG. 15.

In some embodiments, the dielectric platform 1298 of the third dielectric layer 124 and the surface 1238 (underlying the first GAFP electrode layer 1112) of the third dielectric layer 124 are coplanar such that a plane (e.g., a single plane) passes through the dielectric platform 1298 of the third dielectric layer 124 and the surface 1238. In some embodiments, the plane is parallel to the x-axis. In some embodiments, an elevation of the dielectric platform 1298 (relative to the z-axis) is about the same as an elevation of the surface 1238 (underlying the first GAFP electrode layer 1112). In some embodiments, the elevation of the dielectric platform 1298 is less than the elevation of the surface 1238 (underlying the first GAFP electrode layer 1112) by between about 10 angstroms to about 200 angstroms. A width 1296 of the dielectric platform 1298 is between about 20 nanometers to about 40 nanometers. Other values of the width 1296 of the dielectric platform 1298 are within the scope of the present disclosure. In some embodiments, the width 1296 corresponds to a distance, along the x-axis, between the first sidewall 1122 of the GAFP 1108 and the sidewall 1294 of the third dielectric layer 124.

An angle of extension 1213 of the sidewall 1203 of the third GAFP electrode layer 1116 relative to at least one of the surface 1292, the surface 1238, or the x-axis is at least one of at most about 50 degrees, at most about 88 degrees, or at most about 130 degrees. Other values of the angle of extension 1213 are within the scope of the present disclosure. An angle of extension 1215 of the sidewall 1205 of the second GAFP electrode layer 1114 relative to at least one of the surface 1292, the surface 1238, or the x-axis is at least one of between about 50 degrees to about 130 degrees, or between about 50 degrees to about 88 degrees. Other values of the angle of extension 1215 are within the scope of the present disclosure. In some embodiments, the angle of extension 1215 of the sidewall 1205 of the second GAFP electrode layer 1114 is greater than or equal to the angle of extension 1213 of the sidewall 1203 of the third GAFP electrode layer 1116. An angle of extension 1217 of the sidewall 1207 of the first GAFP electrode layer 1112 relative to at least one of the surface 1292, the surface 1238, or the x-axis is at least one of between about 70 degrees to about 120 degrees, greater than about 90 degrees, or greater than about 70 degrees. Other values of the angle of extension 1217 are within the scope of the present disclosure. In some embodiments, the sidewall 1207 of the first GAFP electrode layer 1112 is tapered. In some embodiments, the sidewall 1207 of the first GAFP electrode layer 1112 has a vertical profile and the angle of extension 1217 is about 90 degrees.

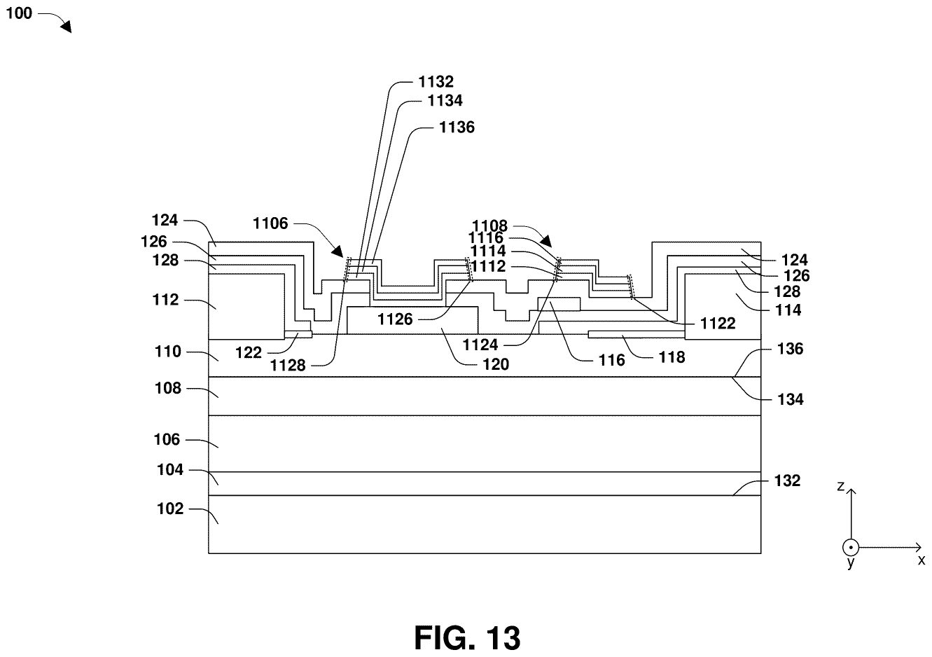

FIG. 13 illustrates removal of the second patterned mask layer 1002, according to some embodiments. In some embodiments, the second patterned mask layer 1002 is removed after the one or more second target layers are patterned to form at least one of the gate electrode 1106 or the GAFP 1108. The second patterned mask layer 1002 is removed by at least one of performing a washing process to wash the second patterned mask layer 1002 away, stripping the second patterned mask layer 1002 away, etching the second patterned mask layer 1002, CMP, or other suitable techniques.

In some embodiments, the GAFP 1108 has the first sidewall 1122 and a second sidewall 1124. In some embodiments, the second sidewall 1124 is formed by the second etching process, such as concurrently while forming the first sidewall 1122 and/or using one, some or all of the techniques provided herein with respect to forming the first sidewall 1122 of the GAFP 1108. In some embodiments, the second sidewall 1124 has one, some, or all of the characteristics and/or features provided herein with respect to the first sidewall 1122 of the GAFP 1108. The second sidewall 1124 is symmetrical or asymmetrical to the first sidewall 1122.

In some embodiments, the gate electrode 1106 has a third sidewall 1126 and a fourth sidewall 1128. In some embodiments, the third sidewall 1126 is formed by the second etching process, such as concurrently while forming the first sidewall 1122 and/or using one, some or all of the techniques provided herein with respect to forming the first sidewall 1122 of the GAFP 1108. In some embodiments, the third sidewall 1126 has one, some, or all of the characteristics and/or features provided herein with respect to the first sidewall 1122 of the GAFP 1108. In some embodiments, the fourth sidewall 1128 is formed by the second etching process, such as concurrently while forming the first sidewall 1122 and/or using one, some or all of the techniques provided herein with respect to forming the first sidewall 1122 of the GAFP 1108. In some embodiments, the fourth sidewall 1128 has one, some, or all of the characteristics and/or features provided herein with respect to the first sidewall 1122 of the GAFP 1108. The fourth sidewall 1128 is symmetrical or asymmetrical to the third sidewall 1126.

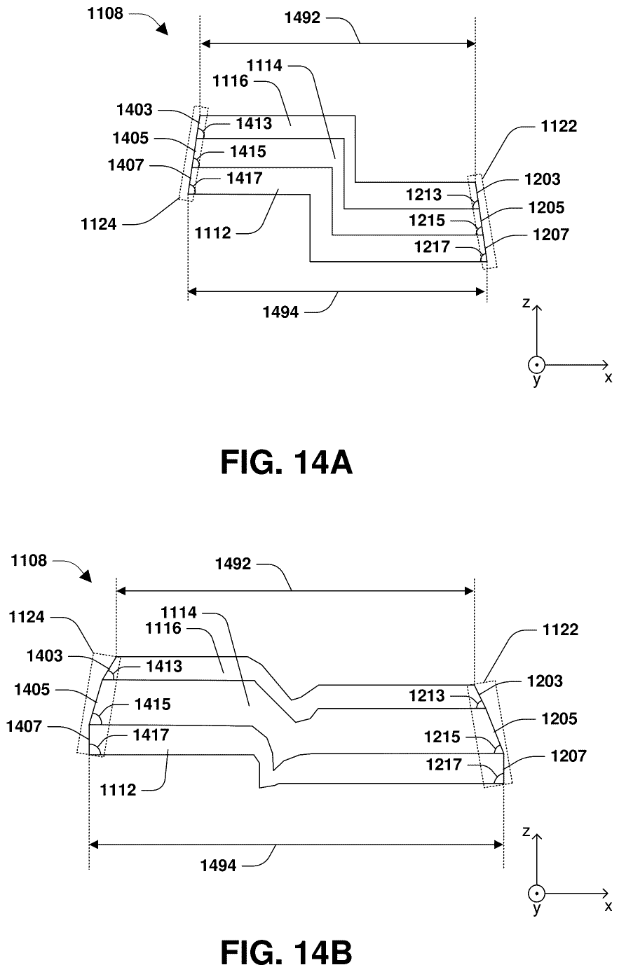

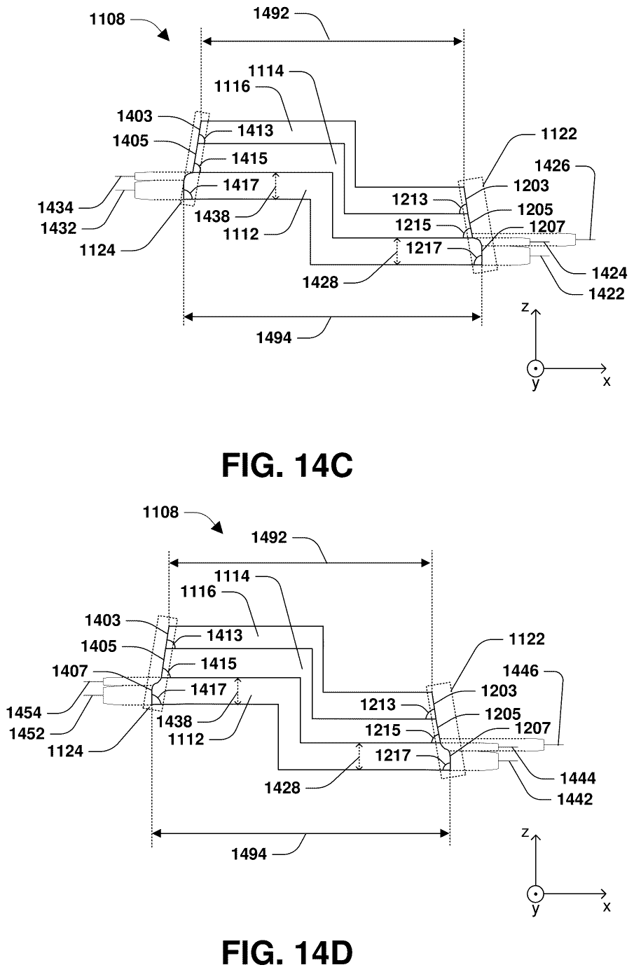

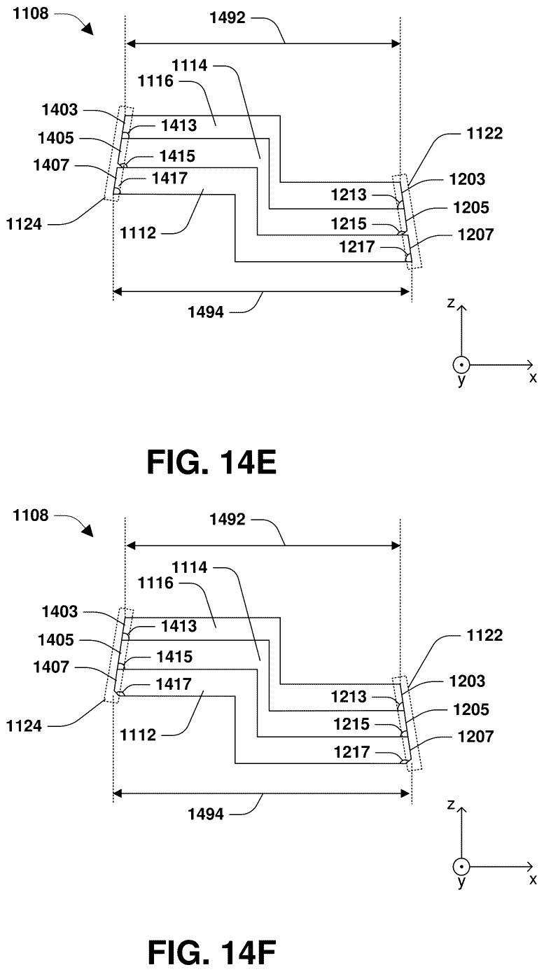

FIGS. 14A-14F illustrate enlarged cross-sectional views of various versions of the GAFP 1108, in accordance with some embodiments. The versions shown in FIGS. 14A-14F have differences in sidewall sizes, sidewall shapes, and/or sidewall angles. In some embodiments, the GAFP 1108 has a trapezoidal shape. In some embodiments, an upper dimension 1492 of the GAFP 1108 is less than a lower dimension 1494 of the GAFP 1108.

In some embodiments, the second sidewall 1124 of the GAFP 1108 comprises a sidewall 1403 of the third GAFP electrode layer 1116, a sidewall 1405 of the second GAFP electrode layer 1114, or a sidewall 1407 of the first GAFP electrode layer 1112. An angle of extension 1413 (shown in FIGS. 14A-14F) of the sidewall 1403 of the third GAFP electrode layer 1116 relative to at least one of the surface 1292, the surface 1238, or the x-axis is at least one of at most about 50 degrees, at most about 88 degrees, or at most about 130 degrees. Other values of the angle of extension 1413 are within the scope of the present disclosure. In some embodiments, the angle of extension 1413 is about equal to the angle of extension 1213 of the sidewall 1203 of the third GAFP electrode layer 1116. In some embodiments, a slope of the sidewall 1403 of the third GAFP electrode layer 1116 is opposite in polarity to a slope of the sidewall 1203 of the third GAFP electrode layer 1116. The sidewall 1403 of the third GAFP electrode layer 1116 is symmetrical or asymmetrical to the sidewall 1203 of the third GAFP electrode layer 1116.

An angle of extension 1415 (shown in FIGS. 14A-14F) of the sidewall 1405 of the second GAFP electrode layer 1114 relative to at least one of the surface 1292, the surface 1238, or the x-axis is at least one of between about 50 degrees to about 130 degrees, or between about 50 degrees to about 88 degrees. Other values of the angle of extension 1415 are within the scope of the present disclosure. In some embodiments, the angle of extension 1415 is about equal to the angle of extension 1215 of the sidewall 1205 of the second GAFP electrode layer 1114. In some embodiments, a slope of the sidewall 1405 of the second GAFP electrode layer 1114 is opposite in polarity to a slope of the sidewall 1205 of the second GAFP electrode layer 1114. In some embodiments, the angle of extension 1415 of the sidewall 1405 of the second GAFP electrode layer 1114 is greater than or equal to the angle of extension 1413 of the sidewall 1403 of the third GAFP electrode layer 1116.

An angle of extension 1417 (shown in FIGS. 14A-14F) of the sidewall 1407 of the first GAFP electrode layer 1112 relative to at least one of the surface 1292, the surface 1238, or the x-axis is at least one of between about 70 degrees to about 120 degrees, greater than about 90 degrees, or greater than about 70 degrees. Other values of the angle of extension 1417 are within the scope of the present disclosure. In some embodiments, the sidewall 1407 of the first GAFP electrode layer 1112 is tapered. In some embodiments, the sidewall 1407 of the first GAFP electrode layer 1112 has a vertical profile and the angle of extension 1417 is about 90 degrees. In some embodiments, the angle of extension 1417 is about equal to the angle of extension 1217 of the sidewall 1207 of the first GAFP electrode layer 1112. In some embodiments, a slope of the sidewall 1407 of the first GAFP electrode layer 1112 is opposite in polarity to a slope of the sidewall 1207 of the first GAFP electrode layer 1112.

FIG. 14A illustrates a first version of the GAFP 1108, in accordance with some embodiments. FIG. 14B illustrates a second version of the GAFP 1108, in accordance with some embodiments. In the second version of the GAFP 1108, at least one of the sidewall 1207 of the first GAFP electrode layer 1112 has a vertical profile or the sidewall 1407 of the first GAFP electrode layer 1112 has a vertical profile, in accordance with some embodiments.

FIG. 14C illustrates a third version of the GAFP 1108, in accordance with some embodiments. In the third version of the GAFP 1108, the sidewall 1207 of the first GAFP electrode layer 1112 has a first bottom segment 1422 that has the angle of extension 1217 and a first convex segment 1424, over the first bottom segment 1422, that has a first convex angular profile with a first variable angle of extension relative to at least one of the surface 1292, the surface 1238, or the x-axis, in accordance with some embodiments. In some embodiments, at least a portion of the first bottom segment 1422 has a vertical profile (e.g., the angle of extension 1217 is about 90 degrees). In some embodiments, at least a portion of the first bottom segment 1422 is tapered. In some embodiments, the angle of extension 1217 is constant or changes along the first bottom segment 1422. In some embodiments, throughout the entirety of the first bottom segment 1422, the angle of extension 1217 is at least one of between about 70 degrees to about 120 degrees, greater than about 90 degrees, or greater than about 70 degrees. In some embodiments, the angle of extension 1217 is constant throughout the entirety of the first bottom segment 1422. In some embodiments, relative to a first vertical extent 1428 of the first GAFP electrode layer 1112 (along the z-axis, for example), the first bottom segment 1422 of the sidewall 1207 spans at least about 25% of the first vertical extent 1428 of the first GAFP electrode layer 1112. In some embodiments, the first bottom segment 1422 of the sidewall 1207 spans at least about 50% of the first vertical extent 1428 of the first GAFP electrode layer 1112. In some embodiments, the first bottom segment 1422 of the sidewall 1207 spans at least about 70% of the first vertical extent 1428 of the first GAFP electrode layer 1112. In some embodiments, the first bottom segment 1422 of the sidewall 1207 spans about 75% of the first vertical extent 1428 of the first GAFP electrode layer 1112. In some embodiments, a length of the first vertical extent 1428 corresponds to the thickness 604 of the first electrode layer 602 (shown in FIG. 6A).

In some embodiments, the first etching operation is configured to form the first convex segment 1424 of the sidewall 1207 to have the first convex angular profile. In some embodiments, the first etching operation ceases etching based upon one or more end point signals detected during the first etching operation. In some embodiments, the etching is stopped at a first point along a first transition region 1426, of the first sidewall 1122, comprising a portion of the sidewall 1205 of the second GAFP electrode layer 1114 and at least a portion of the first bottom segment 1422. In some embodiments, a position of an interface between the second GAFP electrode layer 1114 and the first GAFP electrode layer 1112 is determined based upon the one or more end point signals, and the first point at which the first etching operation ceases etching is determined based upon the position of the interface. In some embodiments, at least one of the first bottom segment 1422 corresponds to the sidewall 1207a (shown in FIG. 12B) of the first portion 1112a of the first GAFP electrode layer 1112, or the first convex segment 1424 corresponds to the sidewall 1207b (shown in FIG. 12E) of the second portion 1112b of the first GAFP electrode layer 1112. In some embodiments, the first convex segment 1424 of the sidewall 1207 is formed to have the first convex angular profile at least partially due to differences between etch rates at different locations of the semiconductor device 100. In some embodiments, at least one of the first halogen-containing gas, the first carrier gas, the first RF power, the first ion bombardment direction, or the first chamber pressure is at least one of selected, controlled, or adjusted (e.g., dynamic in-situ adjustment) to achieve the first convex segment 1424 of the sidewall 1207 having the first convex angular profile, such as by controlling byproducts to facilitate formation of the first convex segment 1424 of the sidewall 1207 having the first convex angular profile.

In the third version of the GAFP 1108, the sidewall 1407 of the first GAFP electrode layer 1112 has a second bottom segment 1432 that has the angle of extension 1417 and a second convex segment 1434, over the second bottom segment 1432, that has a second convex angular profile with a second variable angle of extension relative to at least one of the surface 1292, the surface 1238, or the x-axis, in accordance with some embodiments. In some embodiments, at least a portion of the second bottom segment 1432 has a vertical profile (e.g., the angle of extension 1417 is about 90 degrees). In some embodiments, at least a portion of the second bottom segment 1432 is tapered. In some embodiments, the angle of extension 1417 is constant or changes along the second bottom segment 1432. In some embodiments, throughout the entirety of the second bottom segment 1432, the angle of extension 1417 is at least one of between about 70 degrees to about 120 degrees, greater than about 90 degrees, or greater than about 70 degrees. In some embodiments, the angle of extension 1417 is constant throughout the entirety of the second bottom segment 1432. In some embodiments, relative to a second vertical extent 1438 of the first GAFP electrode layer 1112 (along the z-axis, for example), the second bottom segment 1432 of the sidewall 1407 spans at least about 25% of the second vertical extent 1438 of the first GAFP electrode layer 1112. In some embodiments, the second bottom segment 1432 of the sidewall 1407 spans at least about 50% of the second vertical extent 1438 of the first GAFP electrode layer 1112. In some embodiments, the second bottom segment 1432 of the sidewall 1407 spans at least about 70% of the second vertical extent 1438 of the first GAFP electrode layer 1112. In some embodiments, the second bottom segment 1432 of the sidewall 1407 spans about 75% of the second vertical extent 1438 of the first GAFP electrode layer 1112. In some embodiments, a length of the second vertical extent 1438 corresponds to the thickness 604 of the first electrode layer 602 (shown in FIG. 6A). In some embodiments, the first etching operation forms the second convex segment 1434 of the sidewall 1407 to have the second convex angular profile using one or more of the techniques provided herein with respect to forming the first convex segment 1424 of the sidewall 1207 to have the first convex angular profile.

FIG. 14D illustrates a fourth version of the GAFP 1108, in accordance with some embodiments. In the fourth version of the GAFP 1108, the sidewall 1207 of the first GAFP electrode layer 1112 has a third bottom segment 1442 that has the angle of extension 1217 and a first concave segment 1444, over the third bottom segment 1442, that has a first concave angular profile with a third variable angle of extension relative to at least one of the surface 1292, the surface 1238, or the x-axis, in accordance with some embodiments. In some embodiments, at least a portion of the third bottom segment 1442 has a vertical profile (e.g., the angle of extension 1217 is about 90 degrees). In some embodiments, at least a portion of the third bottom segment 1442 is tapered. In some embodiments, the angle of extension 1217 is constant or changes along the third bottom segment 1442. In some embodiments, throughout the entirety of the third bottom segment 1442, the angle of extension 1217 is at least one of between about 70 degrees to about 120 degrees, greater than about 90 degrees, or greater than about 70 degrees. In some embodiments, the angle of extension 1217 is constant throughout the entirety of the third bottom segment 1442. In some embodiments, the third bottom segment 1442 of the sidewall 1207 spans at least about 25% of the first vertical extent 1428 of the first GAFP electrode layer 1112. In some embodiments, the third bottom segment 1442 of the sidewall 1207 spans at least about 50% of the first vertical extent 1428 of the first GAFP electrode layer 1112. In some embodiments, the third bottom segment 1442 of the sidewall 1207 spans at least about 70% of the first vertical extent 1428 of the first GAFP electrode layer 1112. In some embodiments, the third bottom segment 1442 of the sidewall 1207 spans about 75% of the first vertical extent 1428 of the first GAFP electrode layer 1112.

In some embodiments, the first etching operation is configured to form the first concave segment 1444 of the sidewall 1207 to have the first concave angular profile. In some embodiments, the first etching operation ceases etching based upon one or more end point signals detected during the first etching operation. In some embodiments, the etching is stopped at a first point along a first transition region 1426, of the first sidewall 1122, comprising a portion of the sidewall 1205 of the second GAFP electrode layer 1114 and at least a portion of the third bottom segment 1442. In some embodiments, a position of an interface between the second GAFP electrode layer 1114 and the first GAFP electrode layer 1112 is determined based upon the one or more end point signals, and the first point at which the first etching operation ceases etching is determined based upon the position of the interface. In some embodiments, at least one of the third bottom segment 1442 corresponds to the sidewall 1207a (shown in FIG. 12B) of the first portion 1112a of the first GAFP electrode layer 1112, or the first concave segment 1444 corresponds to the sidewall 1207b (shown in FIG. 12E) of the second portion 1112b of the first GAFP electrode layer 1112. In some embodiments, the first concave segment 1444 of the sidewall 1207 is formed to have the first concave angular profile at least partially due to differences between etch rates at different locations of the semiconductor device 100. In some embodiments, at least one of the first halogen-containing gas, the first carrier gas, the first RF power, the first ion bombardment direction, or the first chamber pressure is at least one of selected, controlled, or adjusted (e.g., dynamic in-situ adjustment) to achieve the first concave segment 1444 of the sidewall 1207 having the first concave angular profile, such as by controlling byproducts to facilitate formation of the first concave segment 1444 of the sidewall 1207 having the first concave angular profile.

In the fourth version of the GAFP 1108, the sidewall 1407 of the first GAFP electrode layer 1112 has a fourth bottom segment 1452 that has the angle of extension 1417 and a second concave segment 1454, over the fourth bottom segment 1452, that has a second concave angular profile with a fourth variable angle of extension relative to at least one of the surface 1292, the surface 1238, or the x-axis, in accordance with some embodiments. In some embodiments, at least a portion of the fourth bottom segment 1452 has a vertical profile (e.g., the angle of extension 1417 is about 90 degrees). In some embodiments, at least a portion of the fourth bottom segment 1452 is tapered. In some embodiments, the angle of extension 1417 is constant or changes along the fourth bottom segment 1452. In some embodiments, throughout the entirety of the fourth bottom segment 1452, the angle of extension 1417 is at least one of between about 70 degrees to about 120 degrees, greater than about 90 degrees, or greater than about 70 degrees. In some embodiments, the angle of extension 1417 is constant throughout the entirety of the fourth bottom segment 1452. In some embodiments, the fourth bottom segment 1452 of the sidewall 1407 spans at least about 25% of the second vertical extent 1438 of the first GAFP electrode layer 1112. In some embodiments, the fourth bottom segment 1452 of the sidewall 1407 spans at least about 50% of the second vertical extent 1438 of the first GAFP electrode layer 1112. In some embodiments, the fourth bottom segment 1452 of the sidewall 1407 spans at least about 70% of the second vertical extent 1438 of the first GAFP electrode layer 1112. In some embodiments, the fourth bottom segment 1452 of the sidewall 1407 spans about 75% of the second vertical extent 1438 of the first GAFP electrode layer 1112. In some embodiments, the first etching operation forms the second concave segment 1454 of the sidewall 1407 to have the second concave angular profile using one or more of the techniques provided herein with respect to forming the first concave segment 1444 of the sidewall 1207 to have the first concave angular profile.

FIG. 14E illustrates a fifth version of the GAFP 1108, in accordance with some embodiments. In the fifth version of the GAFP 1108, at least one of the angle of extension 1215 of the sidewall 1205 of the second GAFP electrode layer 1114 is greater than about 90 degrees or the angle of extension 1415 of the sidewall 1405 of the second GAFP electrode layer 1114 is greater than about 90 degrees, in accordance with some embodiments. FIG. 14F illustrates a sixth version of the GAFP 1108, in accordance with some embodiments. In the sixth version of the GAFP 1108, at least one of the angle of extension 1217 of the sidewall 1207 of the first GAFP electrode layer 1112 is greater than about 90 degrees or the angle of extension 1417 of the sidewall 1407 of the first GAFP electrode layer 1112 is greater than about 90 degrees, in accordance with some embodiments.

FIG. 15 illustrates a fourth dielectric layer 1502 formed over at least one of the third dielectric layer 124, the GAFP 1108, or the gate electrode 1106, in accordance with some embodiments. In some embodiments, the fourth dielectric layer 1502 comprises a low-k dielectric material. In some embodiments, the fourth dielectric layer 1502 comprises at least one of SiO₂, SiON, SiOC, SiOCN, or other suitable material. In some embodiments, the fourth dielectric layer 1502 is formed by at least one of PVD, sputtering, CVD, MOCVD, PECVD, LPCVD, ALCVD, UHVCVD, RPCVD, ALD, MBE, LPE, spin on, growth, or other suitable techniques. The fourth dielectric layer 1502 at least one of overlies the third dielectric layer 124, is in direct contact with a surface of the third dielectric layer 124, or is in indirect contact with the surface of the third dielectric layer 124. The fourth dielectric layer 1502 at least one of overlies the GAFP 1108, is in direct contact with the GAFP 1108, or is in indirect contact with the GAFP 1108. The fourth dielectric layer 1502 at least one of overlies the gate electrode 1106, is in direct contact with the gate electrode 1106, or is in indirect contact with the gate electrode 1106.

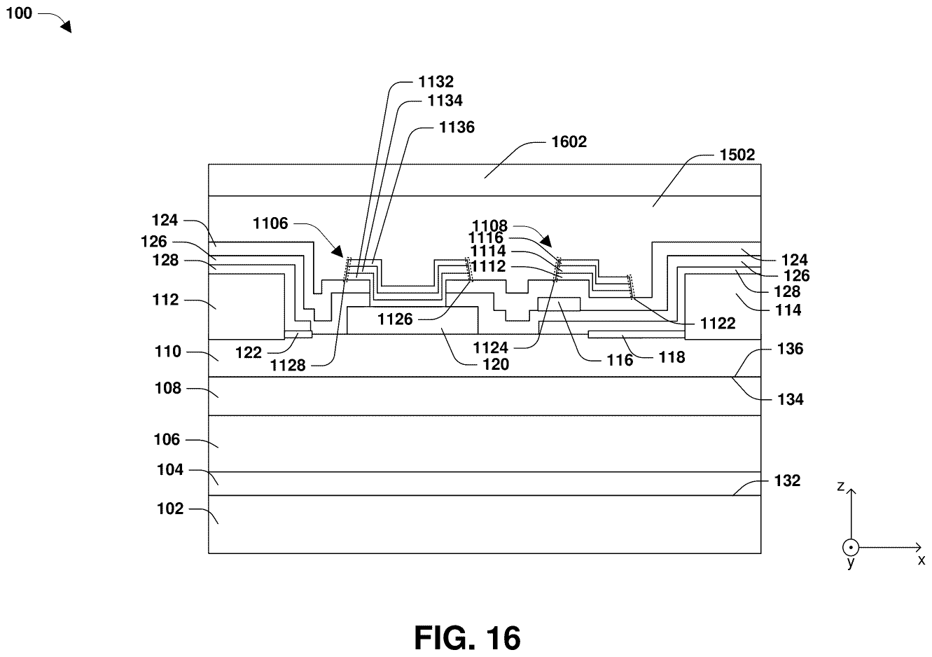

FIG. 16 illustrates a fifth dielectric layer 1602 formed over the fourth dielectric layer 1502, in accordance with some embodiments. In some embodiments, the fifth dielectric layer 1602 comprises at least one of SiO₂ or other suitable material. In some embodiments, the fifth dielectric layer 1602 is formed by at least one of PVD, sputtering, CVD, MOCVD, PECVD, LPCVD, ALCVD, UHVCVD, RPCVD, ALD, MBE, LPE, spin on, growth, or other suitable techniques. The fifth dielectric layer 1602 at least one of overlies the fourth dielectric layer 1502, is in direct contact with a surface of the fourth dielectric layer 1502, or is in indirect contact with the surface of the fourth dielectric layer 1502. In some embodiments, the fourth dielectric layer 1502 comprises at least one of an inter-layer dielectric (ILD) layer or an inter-metal dielectric (IMD) layer.

The fifth dielectric layer 1602 is different than the fourth dielectric layer 1502, such as having a different material composition, such that an interface is defined between the fifth dielectric layer 1602 and the fourth dielectric layer 1502. In some embodiments, the fifth dielectric layer 1602 does not have a material composition different than the fourth dielectric layer 1502. An interface is nevertheless defined between the fifth dielectric layer 1602 and the fourth dielectric layer 1502 because the fifth dielectric layer 1602 and the fourth dielectric layer 1502 are separate, different, etc. layers. In some embodiments, the interface is defined by a discontinuity (e.g., molecular discontinuity, a process-induced discontinuity, etc.) between the fifth dielectric layer 1602 and the fourth dielectric layer 1502 and/or a difference in at least one of crystallinity, molecular structure, dopant concentration, etc. between the fifth dielectric layer 1602 and the fourth dielectric layer 1502.

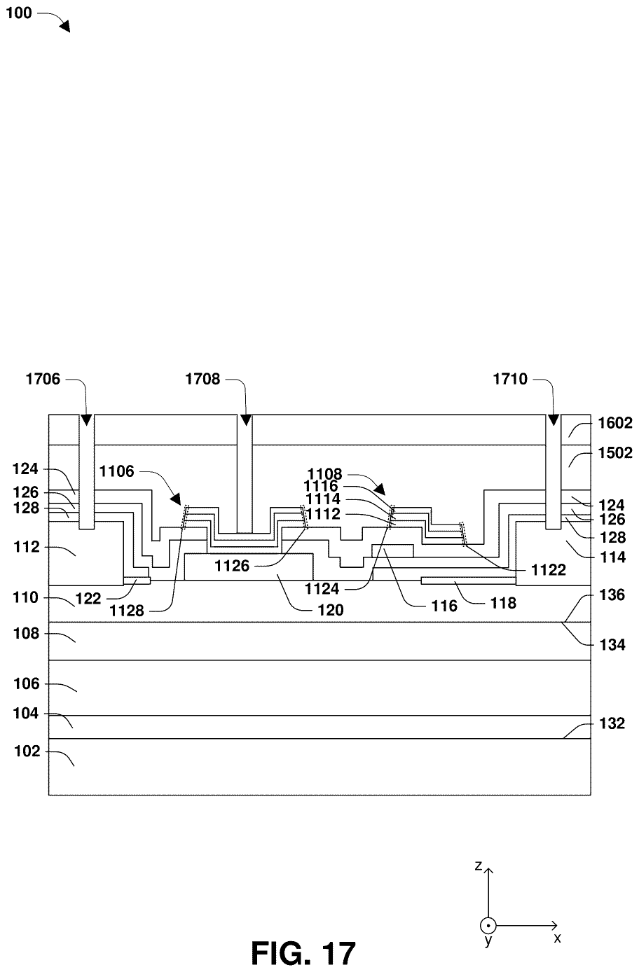

FIG. 17 illustrates a set of trenches formed in the fifth dielectric layer 1602 and the fourth dielectric layer 1502, in accordance with some embodiments. In some embodiments, the set of trenches is formed by at least one of a photolithography process, an etching process, or other suitable process. In some embodiments, the set of trenches comprises a first trench 1706 that exposes a portion of the source electrode 112, a second trench 1708 that exposes a portion of the gate electrode 1106, or a third trench 1710 that exposes a portion of the drain electrode 114.

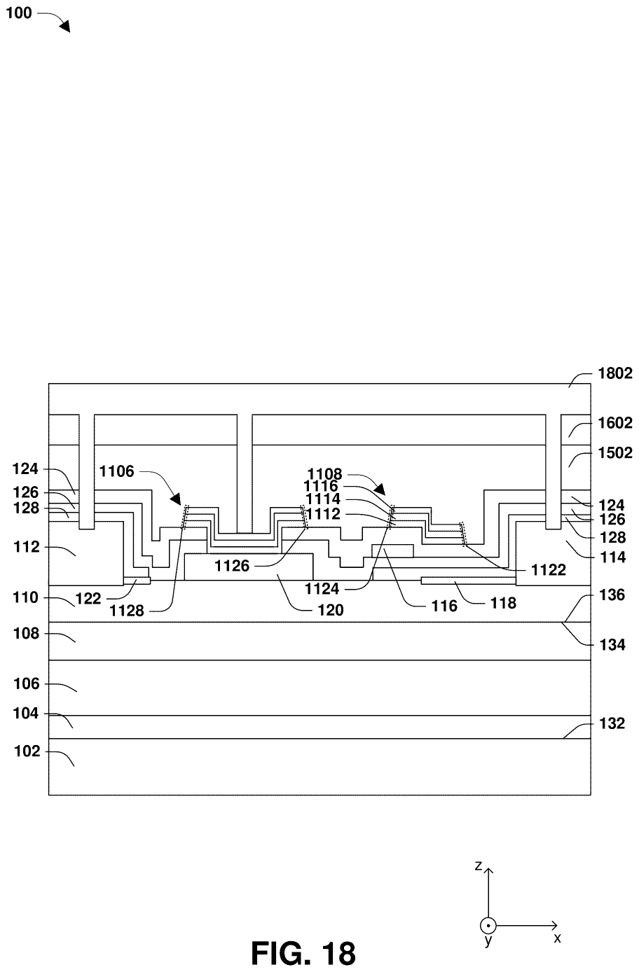

FIG. 18 illustrates a conductive layer 1802 formed over the fifth dielectric layer 1602 and/or in the set of trenches, in accordance with some embodiments. In some embodiments, the conductive layer 1802 comprises at least one of a conductive material, such as one or more metals, or other suitable material. In some embodiments, the conductive layer 1802 is formed by at least one of PVD, sputtering, CVD, MOCVD, PECVD, LPCVD, ALCVD, UHVCVD, RPCVD, ALD, MBE, LPE, spin on, growth, or other suitable techniques. The conductive layer 1802 at least one of overlies the fifth dielectric layer 1602, is in direct contact with a surface of the fifth dielectric layer 1602, or is in indirect contact with the surface of the fifth dielectric layer 1602. The conductive layer 1802 is in direct contact or indirect contact with at least one of the portion of the source electrode 112 exposed by the first trench 1706, the portion of the gate electrode 1106 exposed by the second trench 1708, or the portion of the drain electrode 114 exposed by the third trench 1710.

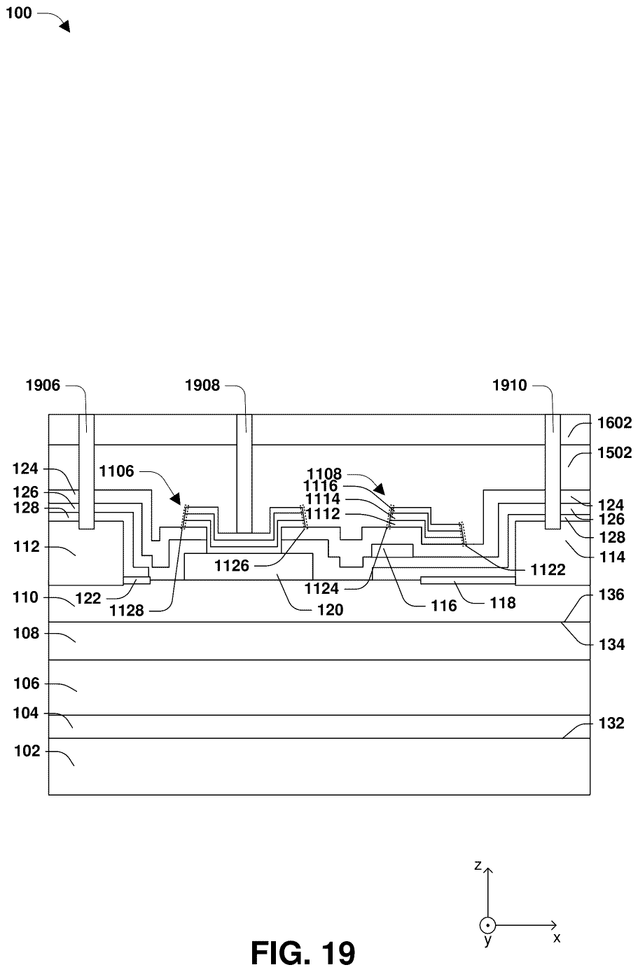

FIG. 19 illustrates removal of a portion of the conductive layer 1802 to form a first set of vias, in accordance with some embodiments. In some embodiments, the first set of vias comprises a via 1906, a via 1908, or a via 1910. In some embodiments, the portion of the conductive layer 1802 is removed by at least one of CMP, etching, or other suitable techniques.

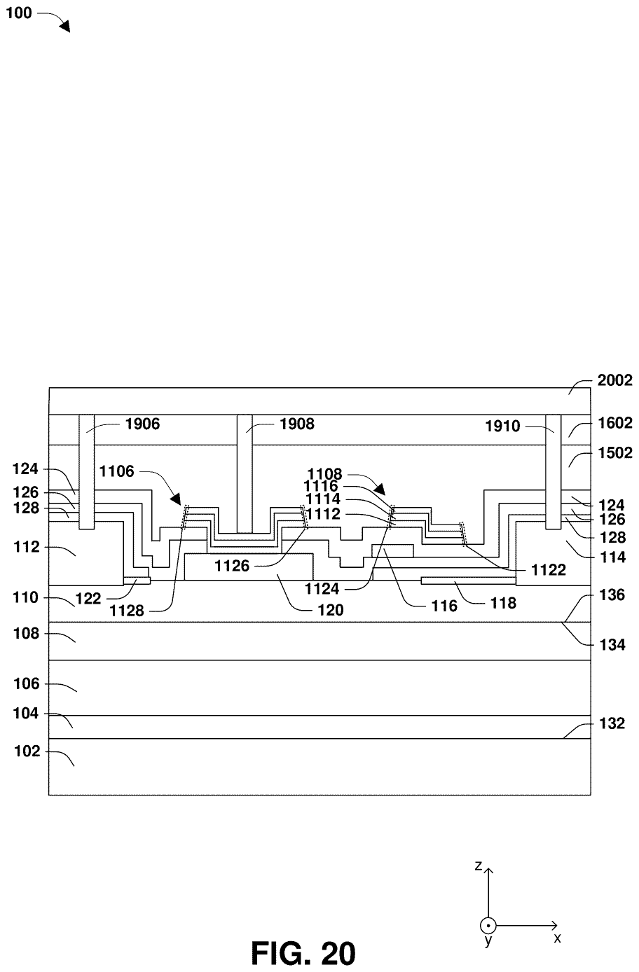

FIG. 20 illustrates a sixth dielectric layer 2002 formed over the fifth dielectric layer 1602, in accordance with some embodiments. In some embodiments, the sixth dielectric layer 2002 comprises at least one of SiO₂ or other suitable material. In some embodiments, the sixth dielectric layer 2002 is formed by at least one of PVD, sputtering, CVD, MOCVD, PECVD, LPCVD, ALCVD, UHVCVD, RPCVD, ALD, MBE, LPE, spin on, growth, or other suitable techniques. The sixth dielectric layer 2002 at least one of overlies the fifth dielectric layer 1602, is in direct contact with a surface of the fifth dielectric layer 1602, or is in indirect contact with the surface of the fifth dielectric layer 1602. In some embodiments, the sixth dielectric layer 2002 comprises at least one of an ILD layer or an IMD layer.

The sixth dielectric layer 2002 is different than the fifth dielectric layer 1602, such as having a different material composition, such that an interface is defined between the sixth dielectric layer 2002 and the fifth dielectric layer 1602. In some embodiments, the sixth dielectric layer 2002 does not have a material composition different than the fifth dielectric layer 1602. An interface is nevertheless defined between the sixth dielectric layer 2002 and the fifth dielectric layer 1602 because the sixth dielectric layer 2002 and the fifth dielectric layer 1602 are separate, different, etc. layers. In some embodiments, the interface is defined by a discontinuity (e.g., molecular discontinuity, a process-induced discontinuity, etc.) between the sixth dielectric layer 2002 and the fifth dielectric layer 1602 and/or a difference in at least one of crystallinity, molecular structure, dopant concentration, etc. between the sixth dielectric layer 2002 and the fifth dielectric layer 1602.

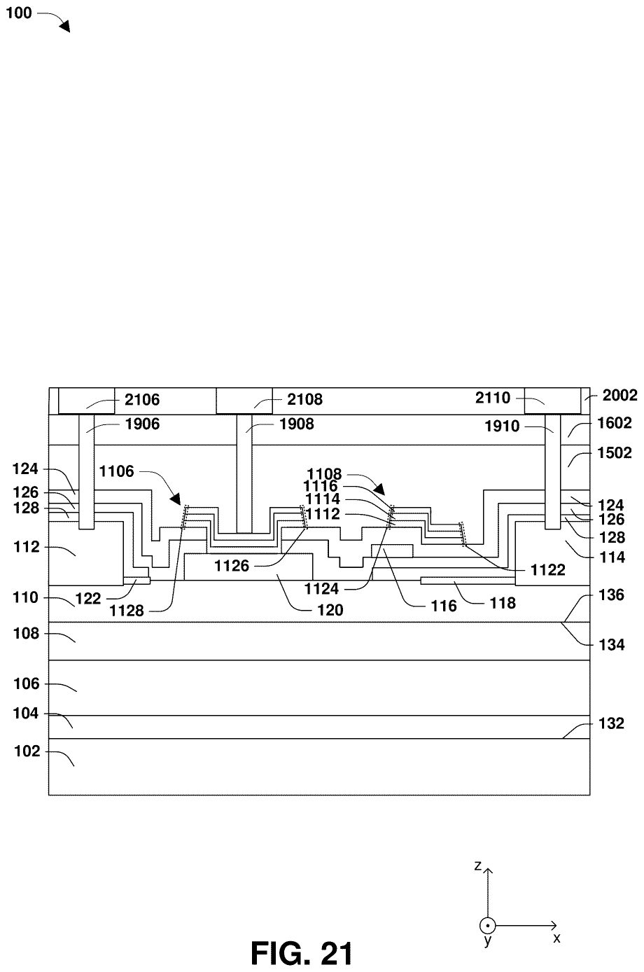

FIG. 21 illustrates forming a first set of conductive lines in the sixth dielectric layer 2002, in accordance with some embodiments. In some embodiments, the first set of conductive lines comprises a conductive line 2106 overlying the via 1906, a conductive line 2108 overlying the via 1908, or a conductive line 2110 overlying the via 1910. In some embodiments, at least one of the first set of vias or the first set of conductive lines is formed by at least one of one or more dual-damascene processes, one or more single-damascene processes, or other suitable process.

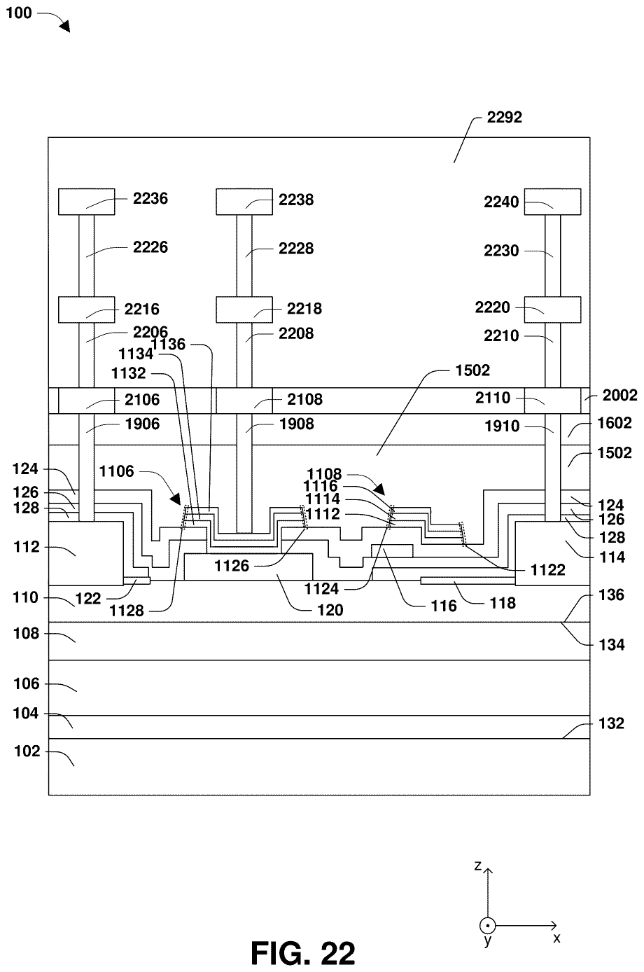

FIG. 22 illustrates formation of one or more dielectric layers 2292 over the sixth dielectric layer 2002 and conductive structures in the one or more dielectric layers 2292. In some embodiments, the one or more dielectric layers 2292 comprise at least one of one or more ILD layers or one or more IMD layers. In some embodiments, the conductive structures comprise at least one of a second set of vias over the first set of conductive lines, a second set of conductive lines over the second set of vias, a third set of vias over the second set of conductive lines, or a third set of conductive lines over the third set of vias. The second set of vias comprises at least one of a via 2206, a via 2208, or a via 2210. The second set of conductive lines comprises at least one of a conductive line 2216, a conductive line 2218, or a conductive line 2220. The third set of vias comprises at least one of a via 2226, a via 2228, or a via 2230. The third set of conductive lines comprises at least one of a conductive line 2236, a conductive line 2238, or a conductive line 2240. Each conductive structure of one, some, or all of the conductive structures comprises a conductive material, such as one or more metals, or other suitable material. In some embodiments, the conductive structures are formed by at least one of one or more dual-damascene processes, one or more single-damascene processes, or other suitable process.

In some embodiments, a work function energy of the gate electrode 1106 is between about 3 electronvolts (eV) to about 5 eV. In some embodiments, a Schottky contact is formed between the feature 120 (e.g., the p-type GaN structure) and the gate electrode 1106. In some embodiments, at least one of the thickness 604, the thickness 704, the thickness 804, a composition of the first electrode layer 602, a composition of the second electrode layer 702, or a composition of the third electrode layer 802 are selected and/or adjusted to adjust the work function energy. In some embodiments, a material (e.g., TiN) of a bottom layer (e.g., the first gate electrode layer 1132) facilitates formation of the Schottky contact. In some embodiments, the feature 120 is configured to deplete charge in a channel region of the semiconductor device 100. In some embodiments, to mitigate dielectric breakdown of one or more dielectric structures of the semiconductor device 100, a film scheme of the one or more dielectric structures varies according to electric field distribution in the one or more dielectric structures during operation of the semiconductor device 100. In some embodiments, the first layer 620 (shown in FIG. 6B) serves as a glue layer to improve adhesion between the GAFP 1108 and the third dielectric layer 124.

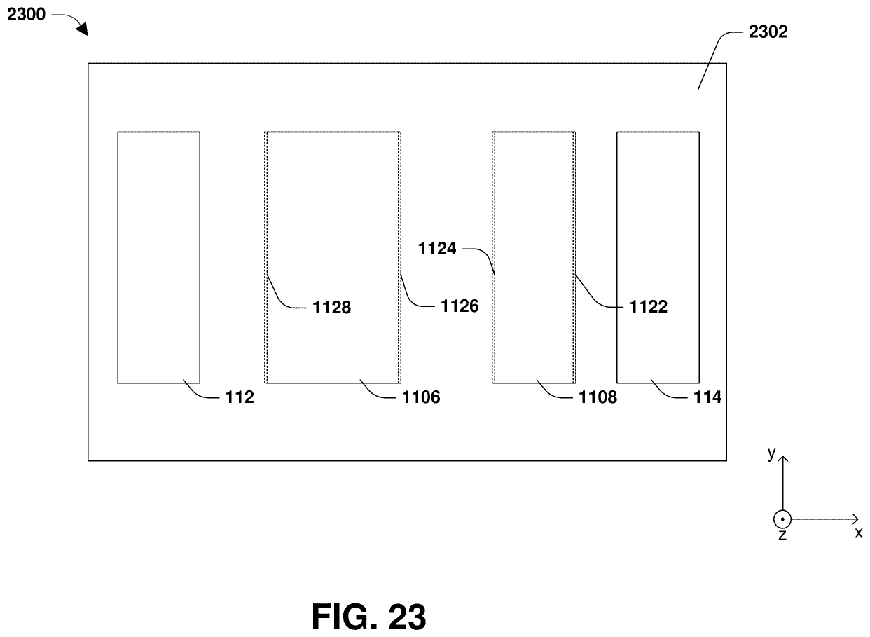

FIG. 23 illustrates an electrode arrangement representation 2300 associated with the semiconductor device 100, in accordance with some embodiments. The electrode arrangement representation 2300 is a top view representation of the source electrode 112, the gate electrode 1106, the GAFP 1108, or the drain electrode 114 arranged relative to each other in a region 2302 of the semiconductor device 100. In some embodiments, the GAFP 1108 is arranged between the drain electrode 114 on a first side and the gate electrode 1106 and the source electrode 112 on a second side.

In some embodiments, at least one of the GAFP 1108 or the field plate 116 is configured to regulate or balance an electric field in the semiconductor device 100, such as an electric field of a region of the semiconductor device 100 between the gate electrode 1106 and the drain electrode 114. Positions of the first sidewall 1122 of the GAFP 1108, the second sidewall 1124 of the GAFP 1108, the third sidewall 1126 of the gate electrode 1106, or the fourth sidewall 1128 of the gate electrode 1106 are illustrated as dashed-line outlined regions. In some embodiments, the first sidewall 1122 at least one of faces or is proximal to the drain electrode 114. In some embodiments, at least one of the GAFP 1108 or the field plate 116 is electrically connected to the source electrode 112, such as through one or more conductive structures of at least one of the first set of vias, the first set of conductive lines, the second set of vias, the second set of conductive lines, the third set of vias, the third set of conductive lines, or one or more other conductive structures.

In some systems, at least one of the first sidewall 1122, the second sidewall 1124, the third sidewall 1126, or the fourth sidewall 1128 is formed to have a foot defect, such as a protrusion extending in a horizontal direction from the sidewall 1207, which contributes to at least one of electrical field crowding, an increase of an electric field density (in a region between the foot defect and the drain electrode 114, for example), an electrical field imbalance, etc. In some embodiments, forming at least one of the first sidewall 1122, the second sidewall 1124, the third sidewall 1126, or the fourth sidewall 1128 to have one or more of the characteristics disclosed herein (e.g., not having the footing defect at a bottom segment of a bottom layer, such as the first GAFP electrode layer 1112, of the GAFP 1108) provides for at least one of improved regulation or increased stability of the electric field in the semiconductor device 100, thereby providing for at least one of enhanced breakdown voltage of the semiconductor device 100, improved reliability of the semiconductor device 100, increased chip probe (CP) yield, reduced failure rate (e.g., less likelihood of burnout between the GAFP 1108 and the drain electrode 114), etc., such as due, at least in part, to increased uniformity of distances between the first sidewall 1122 of the GAFP 1108 and the drain electrode 114 along a y-axis (shown in FIGS. 1-23) and the z-axis, as compared with implementations having the footing defect at a bottom of the first sidewall 1122 which causes changes in distance between the first sidewall 1122 of the GAFP 1108 and the drain electrode 114 that at least one of increases electric field crowding between the footing defect and the drain electrode 114, decreases breakdown voltage of the semiconductor device 100, reduces CP yield, reduces reliability, etc.

In some systems, the GAFP 1108 is formed to have a bottom layer, such as the first GAFP electrode layer 1112, that has a sidewall which faces the drain electrode 114 and has an angle of extension that is less than a first threshold angle of extension, such as 70 degrees, which has an adverse effect on subsequent dielectric coverage (e.g., coverage and/or contact of the fourth dielectric layer 1502 relative to the GAFP 1108). In some embodiments, forming a bottom layer (e.g., the first GAFP electrode layer 1112) of the GAFP 1108 to have the angle of extension 1217 greater than the first threshold angle of extension (e.g., about 70 degrees) provides for at least one of an improvement to the subsequent dielectric coverage, or improved regulation or increased stability of the electric field in the semiconductor device 100, enhanced breakdown voltage of the semiconductor device 100, improved reliability of the semiconductor device 100, increased CP yield, reduced failure rate (e.g., less likelihood of burnout between the GAFP 1108 and the drain electrode 114), etc.

In some systems, the GAFP 1108 is formed to have a bottom layer, such as the first GAFP electrode layer 1112, that has a sidewall which faces the drain electrode 114 and has an angle of extension that is greater than a second threshold angle of extension, such as 120 degrees, which has an adverse effect on subsequent dielectric coverage (e.g., coverage and/or contact of the fourth dielectric layer 1502 relative to the GAFP 1108). In some embodiments, forming a bottom layer (e.g., the first GAFP electrode layer 1112) of the GAFP 1108 to have the angle of extension 1217 greater than the second threshold angle of extension (e.g., about 120 degrees) provides for at least one of an improvement to the subsequent dielectric coverage, or improved regulation or increased stability of the electric field in the semiconductor device 100, enhanced breakdown voltage of the semiconductor device 100, improved reliability of the semiconductor device 100, increased CP yield, reduced failure rate (e.g., less likelihood of burnout between the GAFP 1108 and the drain electrode 114), etc.

Embodiments are contemplated in which at least one of the gate electrode 1106 or the GAFP 1108 is formed from a single electrode layer, two electrode layers, four electrode layers, or other suitable quantity of electrode layers.

According to some embodiments, at least one of the relative dimensions (e.g., the first thickness 1232 of the first byproducts 1220 on the GAFP 1108 being greater than the second thickness 1234 of the second byproducts 1222 on the residual electrode layer 1224), etching techniques of the second etching process (e.g., one or more RF powers used by the second etching process, one or more etching process types associated with etching operations and/or stages of the second etching process, one or more processing times associated with etching operations and/or stages of the second etching process, etching chemicals used by the second etching process, etc.), or ratios and/or relationships between at least one of RF powers, flow rate ratios, processing times, etc., of various etching operations and/or stages of the second etching operation, are important (e.g., critical) because they facilitate achieving desired sidewall profiles of at least one of the first sidewall 1122, the second sidewall 1124, the third sidewall 1126, or the fourth sidewall 1128, such as due, at least in part, to at least one of the first sidewall 1122, the second sidewall 1124, the third sidewall 1126, or the fourth sidewall 1128 being sufficiently protected in the second etching process.

In some embodiments, a method is provided. The method includes forming an electrode layer over a first dielectric layer. The method includes performing a first etching operation to pattern the electrode layer and form a gate electrode, a gate field plate (GAFP), a residual electrode layer adjacent the GAFP and overlying the first dielectric layer, first byproducts on the GAFP, and second byproducts on the residual electrode layer. The method includes performing a second etching operation to remove the second byproducts from the residual electrode layer and to remove a first portion of the first byproducts, wherein a second portion of the first byproducts remain on the GAFP after the second etching operation. The method includes performing a third etching operation to remove the residual electrode layer.

In some embodiments, the method includes forming a drain electrode, and forming a second dielectric layer over the GAFP, wherein a portion of the second dielectric layer is between the GAFP and the drain electrode.

In some embodiments, performing the third etching operation includes performing a first etching stage to remove the residual electrode layer to expose a portion of the first dielectric layer, wherein an amount of the second portion of the first byproducts remains on the GAFP after the first etching stage, and performing a second etching stage to remove the amount of the second portion of the first byproducts.

In some embodiments, performing the second etching stage includes removing the portion of the first dielectric layer.

In some embodiments, performing the first etching operation includes performing the first etching operation such that a first thickness of the first byproducts on the GAFP is greater than a second thickness of the second byproducts on the residual electrode layer.

In some embodiments, the method includes forming a mask layer over the electrode layer, wherein at least one of performing the first etching operation, performing the second etching operation, or performing the third etching operation is performed using the mask layer.

In some embodiments, at least one of the first byproducts or the second byproducts include at least one of residue from the mask layer, residue from the electrode layer, residue from an etching gas used by the first etching operation, residue from an etching tool used by the first etching operation, or one or more products of one or more chemical reactions induced by the first etching operation.

In some embodiments, forming the electrode layer includes forming a first layer over the first dielectric layer, and forming a second layer over the first layer.

In some embodiments, performing the first etching operation includes patterning the second layer to form a first GAFP electrode layer, and removing a first portion of the first layer to form a first portion of a second GAFP electrode layer under the first GAFP electrode layer. Performing the third etching operation includes removing the residual electrode layer, that includes a second portion of the first layer under the first portion of the first layer, to form a second portion of the second GAFP electrode layer under the first portion of the second GAFP electrode layer. A sidewall of the GAFP includes a first sidewall of the first GAFP electrode layer, a second sidewall of the first portion of the second GAFP electrode layer, and a third sidewall of the second portion of the second GAFP electrode layer.

In some embodiments, at least one of performing the first etching operation includes performing the first etching operation such that at least one of the first sidewall or the second sidewall is tapered, or performing the third etching operation includes performing the third etching operation such that the third sidewall is tapered.

In some embodiments, at least one of performing the first etching operation includes performing the first etching operation such that a first angle of extension of the first sidewall relative to a surface of the first dielectric layer is between about 50 degrees to about 130 degrees, or performing the third etching operation includes performing the third etching operation such that a second angle of extension of the third sidewall relative to the surface of the first dielectric layer is at least about 70 degrees.

In some embodiments, a semiconductor device is provided. The semiconductor device includes a substrate, a source electrode over the substrate, a drain electrode over the substrate, a gate electrode between the source electrode and the drain electrode, and a multi-layer gate field plate (GAFP) including a bottom layer having a sidewall proximal the drain electrode. An angle of extension of an entirety of a bottom segment of the sidewall relative to a surface of the substrate is between about 50 degrees to about 130 degrees, wherein the bottom segment of the sidewall spans at least about 25% of a vertical extent of the bottom layer.

In some embodiments, the semiconductor device includes a gallium nitride layer between the substrate and at least one of the source electrode, the drain electrode, the gate electrode, or the multi-layer GAFP.

In some embodiments, the multi-layer GAFP includes a second layer over the bottom layer.

In some embodiments, the bottom layer includes titanium nitride, and the second layer includes aluminum copper.

In some embodiments, the multi-layer GAFP includes a third layer over the second layer.

In some embodiments, the third layer includes titanium nitride.

In some embodiments, a method is provided. The method includes performing a first etching operation to pattern an electrode layer, that is over a first dielectric layer, and form a gate electrode, a gate field plate (GAFP), a residual electrode layer adjacent to the GAFP and overlying the first dielectric layer, first byproducts on a sidewall of the GAFP, and second byproducts on a surface of the residual electrode layer. The method includes performing a second etching operation to remove the second byproducts from the surface of the residual electrode layer and to remove a first portion of the first byproducts, wherein a second portion of the first byproducts remain on the sidewall of the GAFP after the second etching operation. The method includes performing a third etching operation to remove the residual electrode layer.

In some embodiments, performing the first etching operation includes applying a first radio frequency (RF) power to generate first plasma, and performing the second etching operation includes applying a second RF power to generate second plasma, wherein the second RF power is less than the first RF power.

In some embodiments, performing the third etching operation includes applying a third RF power to generate third plasma, wherein the third RF power is less than the first RF power.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method of forming a semiconductor device, comprising:
forming an electrode layer over a first dielectric layer;
performing a first etching operation to pattern the electrode layer and form:
a gate electrode;
a gate field plate (GAFP);
a residual electrode layer adjacent the GAFP and overlying the first dielectric layer;
first byproducts on the GAFP; and
second byproducts on the residual electrode layer;
performing a second etching operation to remove the second byproducts from the residual electrode layer and to remove a first portion of the first byproducts, wherein a second portion of the first byproducts remain on the GAFP after the second etching operation; and
performing a third etching operation to remove the residual electrode layer.

2. The method of claim 1, comprising:
forming a drain electrode; and
forming a second dielectric layer over the GAFP, wherein a portion of the second dielectric layer is between the GAFP and the drain electrode.

3. The method of claim 1, wherein performing the third etching operation comprises:
performing a first etching stage to remove the residual electrode layer to expose a portion of the first dielectric layer, wherein an amount of the second portion of the first byproducts remains on the GAFP after the first etching stage; and
performing a second etching stage to remove the amount of the second portion of the first byproducts.

4. The method of claim 3, wherein performing the second etching stage comprises:
removing the portion of the first dielectric layer.

5. The method of claim 1, wherein performing the first etching operation comprises:
performing the first etching operation such that a first thickness of the first byproducts on the GAFP is greater than a second thickness of the second byproducts on the residual electrode layer.

6. The method of claim 1, comprising:
forming a mask layer over the electrode layer, wherein at least one of performing the first etching operation, performing the second etching operation, or performing the third etching operation is performed using the mask layer.

7. The method of claim 6, wherein:
at least one of the first byproducts or the second byproducts comprise at least one of residue from the mask layer, residue from the electrode layer, residue from an etching gas used by the first etching operation, residue from an etching tool used by the first etching operation, or one or more products of one or more chemical reactions induced by the first etching operation.

8. The method of claim 1, wherein forming the electrode layer comprises:
forming a first layer over the first dielectric layer; and
forming a second layer over the first layer.

9. The method of claim 8, wherein:
performing the first etching operation comprises:
patterning the second layer to form a first GAFP electrode layer; and
removing a first portion of the first layer to form a first portion of a second GAFP electrode layer under the first GAFP electrode layer;
performing the third etching operation comprises removing the residual electrode layer, that comprises a second portion of the first layer under the first portion of the first layer, to form a second portion of the second GAFP electrode layer under the first portion of the second GAFP electrode layer; and
a sidewall of the GAFP comprises a first sidewall of the first GAFP electrode layer, a second sidewall of the first portion of the second GAFP electrode layer, and a third sidewall of the second portion of the second GAFP electrode layer.

10. The method of claim 9, wherein at least one of:
performing the first etching operation comprises performing the first etching operation such that at least one of the first sidewall or the second sidewall is tapered;
or performing the third etching operation comprises performing the third etching operation such that the third sidewall is tapered.

11. The method of claim 9, wherein at least one of:
performing the first etching operation comprises performing the first etching operation such that a first angle of extension of the first sidewall relative to a surface of the first dielectric layer is between about 50 degrees to about 130 degrees; or
performing the third etching operation comprises performing the third etching operation such that a second angle of extension of the third sidewall relative to the surface of the first dielectric layer is at least about 70 degrees.

12. A semiconductor device comprising:
a substrate;
a source electrode over the substrate;
a drain electrode over the substrate;
a gate electrode between the source electrode and the drain electrode; and
a multi-layer gate field plate (GAFP) comprising a bottom layer having a sidewall proximal the drain electrode, wherein an angle of extension of an entirety of a bottom segment of the sidewall relative to a surface of the substrate is between about 50 degrees to about 130 degrees, wherein the bottom segment of the sidewall spans at least about 25% of a vertical extent of the bottom layer.

13. The semiconductor device of claim 12, comprising:
a gallium nitride layer between the substrate and at least one of the source electrode, the drain electrode, the gate electrode, or the multi-layer GAFP.

14. The semiconductor device of claim 12, wherein:
the multi-layer GAFP comprises a second layer over the bottom layer.

15. The semiconductor device of claim 14, wherein:
the bottom layer comprises titanium nitride; and
the second layer comprises aluminum copper.

16. The semiconductor device of claim 15, wherein:
the multi-layer GAFP comprises a third layer over the second layer.

17. The semiconductor device of claim 16, wherein:
the third layer comprises titanium nitride.

18. A method of forming a semiconductor device, comprising:
performing a first etching operation to pattern an electrode layer, that is over a first dielectric layer, and form:
a gate electrode;
a gate field plate (GAFP);
a residual electrode layer adjacent to the GAFP and overlying the first dielectric layer;
first byproducts on a sidewall of the GAFP; and
second byproducts on a surface of the residual electrode layer;
performing a second etching operation to remove the second byproducts from the surface of the residual electrode layer and to remove a first portion of the first byproducts, wherein a second portion of the first byproducts remain on the sidewall of the GAFP after the second etching operation; and
performing a third etching operation to remove the residual electrode layer.

19. The method of claim 18, wherein:
performing the first etching operation comprises applying a first radio frequency (RF) power to generate first plasma; and
performing the second etching operation comprises applying a second RF power to generate second plasma, wherein the second RF power is less than the first RF power.

20. The method of claim 19, wherein performing the third etching operation comprises:
applying a third RF power to generate third plasma, wherein the third RF power is less than the first RF power.
